(19) United States
(12) Patent Application Publication
(10) Pub. No.: US 2020/0064660 A1
(43) Pub. Date: Feb. 27, 2020

(54) OPTICAL COMMUNICATION OF OPHTHALMIC DEVICES

(71) Applicant: Johnson & Johnson Vision Care, Inc., Jacksonville, FL (US)

(72) Inventors: Donald Scott Langford, Melbourne, FL (US); Donald K. Whitney, Melbourne, FL (US); Adam Toner, Jacksonville, FL (US)

(21) Appl. No.: 16/112,315

(22) Filed: Aug. 24, 2018

(51) Int. Cl. G02C 11/00; G02C 7/04; G02C 7/08; H01L 25/16; H01L 23/538

(52) U.S. Cl. CPC G02C 11/10; G02C 7/041; H01L 33/0016; H01L 25/167; H01L 23/5387; G02C 7/081

(57) ABSTRACT

The present disclosure relates to a communication systems for electronic ophthalmic devices. In certain embodiments, the ophthalmic device may comprise a light-emitting device. The ophthalmic device may comprise a light detection device. The light detection device may be used to receive light signals. The light-emitting device may be used to transmit light signals.

### BACKGROUND OF THE DISCLOSURE

### 1. Field of the Disclosure

The present disclosure relates to electronic ophthalmic devices, such as wearable lenses, including contact lenses, implantable lenses, including intraocular lenses (IOLs) and any other type of device comprising optical components, and more particularly, to sensors and associated hardware and software for detecting various signals in an individual to activate and control electronic ophthalmic devices including transmission of communication signals from the electronic ophthalmic devices.

### 2. Discussion of the Related Art

Ophthalmic devices, such as contact lenses and intraocular lenses, currently are utilized to correct vision defects such as myopia (nearsightedness), hyperopia (farsightedness), presbyopia and astigmatism. However, properly designed lenses incorporating additional components may be utilized to enhance vision as well as to correct vision defects.

Ophthalmic devices may incorporate a lens assembly having an electronically adjustable focus to augment or enhance performance of the eye. The use of embedded electronics in a lens assembly introduces a potential requirement for communication with the electronics, for a method of powering and/or re-energizing the electronics, for interconnecting the electronics, for internal and external sensing and/or monitoring, and for control of the electronics and the overall function of the lens.

Conventional contact lenses are polymeric structures with specific shapes to correct various vision problems as briefly set forth above. To achieve enhanced functionality, various circuits and components have to be integrated into these polymeric structures. For example, control circuits, microprocessors, communication devices, power supplies, sensors, actuators, light-emitting diodes, and miniature antennas may be integrated into contact lenses via custom-built optoelectronic components to not only correct vision, but to enhance vision as well as provide additional functionality as is explained herein.

In addition, because of the complexity of the functionality associated with a powered ophthalmic device and the high level of interaction between its components, there is a need to coordinate and control the overall operation of the electronics and optics. Further, there is often a need to transmit information to and from the ophthalmic device.

### SUMMARY OF THE DISCLOSURE

The present disclosure relates to powered ophthalmic devices that comprise an electronic system that, in turn, performs any number of functions, including actuating a variable-focus optic if included. The electronic system may include one or more batteries or other power sources, power management circuitry, one or more sensors, clock generation circuitry, control algorithms, circuitry comprising a sensor, lens driver circuitry, and a light source configured to transmit a signal (e.g., communication signal, optical communication) from the powered ophthalmic devices.

Powered or electronic ophthalmic devices may have to account for the various conditions and characteristics of a user. For example, ciliary muscle signals may be detected from an individual utilizing the powered or electronic ophthalmic devices. More specifically, powered ophthalmic devices may need to detect and differentiate between various ciliary muscle signals (e.g., vibrations), and from one or more of other signals, noise, and interference. As a further example, other signals indicative of conditions and characteristics may be detected using capacitance sensors, temperature sensors, displacement sensors, optical sensors, and the like.

The present disclosure relates to electronic ophthalmic devices comprising one or more sensor systems described herein. In certain embodiments, an ophthalmic device may comprise an ophthalmic lens having an optic zone and a peripheral zone. A variable optic element may be incorporated into the optic zone of the ophthalmic lens. The variable optic may be configured to change the refractive power of the wearable ophthalmic lens. A sensor may be disposed in the peripheral zone of the ophthalmic lens. The sensor may be configured to detect a characteristic of a user of the ophthalmic device. The sensor may further be configured to provide an output. A light source may be configured to transmit a light signal outwardly from the ophthalmic device. The light signal may represent at least the output of the sensor.

The present disclosure relates to sensor systems. In certain embodiments, a sensor system may comprise a sensor disposed adjacent an eye of a user. The sensor may be configured to detect a characteristic of the user. The sensor may further be configured to provide an output. A light source may be configured to transmit a light signal outwardly from the eye of the user. The light signal may represent at least the output of the sensor. A receiver may be spaced from the eye of the user. The receiver may be configured to receive the light signal and to process the received light signal to extract an indication of the output of the sensor. As an example, the receiver may comprise a photodetector configured to receive the light signal.

The present disclosure may relate to an example ophthalmic device. The ophthalmic device may comprise an ophthalmic lens configured to be disposed on or in an eye of a user. The ophthalmic lens may have an optic zone and a peripheral zone. The ophthalmic device may comprise a variable optic element incorporated into the optic zone of the ophthalmic lens. The variable optic element may be configured to change a refractive power of the ophthalmic lens. The ophthalmic device may comprise a sensor disposed in the peripheral zone of the ophthalmic lens. The sensor may be configured to detect a characteristic of a user of the ophthalmic device. The sensor may be further configured to provide a sensor output. The ophthalmic device may comprise a processor disposed in the peripheral zone of the ophthalmic lens. The processor may be configured to determine communication data based on the sensor output. The ophthalmic device may comprise a power source configured to supply power to at least one of the ophthalmic lens, the sensor, and the processor. The ophthalmic device may comprise a light-emitting device configured to transmit a light signal outwardly from the ophthalmic device. The light signal may represent the communication data. The light-emitting device may comprise a photonic transmitter comprising one or more of a reverse-biased silicon diode (RSiD) or an organic LED (OLED). The light-emitting device may comprise a driving circuit electrically coupled to the photonic transmitter and configured to cause the photonic transmitter to generate the light signal based on the communication data. The driving circuit may be configured to generate a first voltage larger than a second voltage of the power source and switch a connection between the photonic transmitter and the first voltage on and off to generate the light signal.

The present disclosure relates to another example ophthalmic device. The ophthalmic device may comprise an ophthalmic lens configured to be disposed on or in an eye of a user. The ophthalmic lens may have an optic zone and a peripheral zone. The ophthalmic device may comprise a variable optic element incorporated into the optic zone of the ophthalmic lens. The variable optic element may be configured to change a refractive power of the ophthalmic lens. The ophthalmic device may comprise a sensor disposed in the peripheral zone of the ophthalmic lens. The sensor may be configured to detect a characteristic of a user of the ophthalmic device. The sensor may further be configured to provide a sensor output. The ophthalmic device may comprise a processor disposed in the peripheral zone of the ophthalmic lens. The processor may be configured to determine communication data based on the sensor output. The ophthalmic device may comprise a power source configured to supply power to at least one of the ophthalmic lens, the sensor, and the processor. The ophthalmic device may comprise a light-emitting device configured to transmit a light signal outwardly from the ophthalmic device. The light signal may represent the communication data. The light-emitting device may comprise a photonic transmitter comprising an electro-luminescent (EL) device. The light-emitting device may comprise a driving circuit electrically coupled to the photonic transmitter and configured to cause the photonic transmitter to generate the light signal based on the communication data. The driving circuit may be configured to generate a first voltage larger than a second voltage of the power source and switch a connection between the photonic transmitter and the first voltage on and off to generate the light signal.

The present disclosure relates to another example ophthalmic device. The ophthalmic device may comprise an ophthalmic lens configured to be disposed on or in an eye of a user. The ophthalmic lens may have an optic zone and a peripheral zone. The ophthalmic device may comprise a variable optic element incorporated into the optic zone of the ophthalmic lens. The variable optic element may be configured to change a refractive power of the ophthalmic lens. The ophthalmic device may comprise a light detection device configured to generate a data signal based on light received at the ophthalmic device. The light detection device may comprise a photonic detector configured to convert light pulses into electrical signals. The light detection device may comprise a filter electrically coupled to the photonic detector and configured to output filtered signals within a predetermined frequency range based on the electrical signals. The light detection device may comprise a converter electrically coupled to the filter and configured to output the data signal based on the filtered signals. The data signal may comprise a digital signal of variable pulse width based on time-varying characteristics of the filtered signals. The ophthalmic device may further comprise a processor disposed in the peripheral zone of the ophthalmic lens. The processor may be configured to determine communication data based on the data signal.

The present disclosure relates to another ophthalmic device. The ophthalmic device may comprise an ophthalmic lens configured to be disposed on or in an eye of a user. The ophthalmic lens may have an optic zone and a peripheral zone. The ophthalmic device may comprise a variable optic element incorporated into the optic zone of the ophthalmic lens. The variable optic element may be configured to change a refractive power of the ophthalmic lens. The ophthalmic device may comprise a sensor disposed in the peripheral zone of the ophthalmic lens. The sensor may be configured to detect a characteristic of a user of the ophthalmic device. The sensor may further be configured to provide a sensor output. The ophthalmic device may comprise a processor disposed in the peripheral zone of the ophthalmic lens. The processor may be configured to determine communication data based on the sensor output. The ophthalmic device may comprise a power source configured to supply power to at least one of the ophthalmic lens, the sensor, and the processor. The ophthalmic device may comprise a light-emitting device configured to transmit a light signal outwardly from the ophthalmic device. The light signal may represent the communication data. The light-emitting device may comprise a photonic transmitter comprising a light-emitting transistor. The light emitting device may comprise a driving circuit electrically coupled to the photonic transmitter and configured to cause the photonic transmitter to generate the light signal based on the communication data. The driving circuit may be configured to generate a first voltage larger than a second voltage of the power source and cause a current based on the first voltage to switch on and off for the photonic transmitter to generate the light signal.

The present disclosure relates to another ophthalmic device. The ophthalmic device may comprise an ophthalmic lens configured to be disposed on or in an eye of a user. The ophthalmic lens may have an optic zone and a peripheral zone. The ophthalmic device may comprise a variable optic element incorporated into the optic zone of the ophthalmic lens. The variable optic element may be configured to change a refractive power of the ophthalmic lens. The ophthalmic device may comprise a processor disposed in the peripheral zone of the ophthalmic lens. The processor may be configured to determine communication data associated with communicating with the user. The ophthalmic device may comprise a power source configured to supply power to at least one of the ophthalmic lens and the processor. The ophthalmic device may comprise a light-emitting device configured to transmit a light signal from the ophthalmic device to the eye of the user. The light signal may represent the communication data. The light-emitting device may comprise a photonic transmitter. The ophthalmic device may comprise a driving circuit electrically coupled to the photonic transmitter and configured to cause the photonic transmitter to generate the light signal based on the communication data. The driving circuit may be configured to generate a first voltage larger than a second voltage of the power source and switch a connection between the photonic transmitter and the first voltage on and off to generate the light signal.

Conventional light emitting devices may be too large or may require too much power to be integrated into an ophthalmic device. The present methods and systems overcome these problems through the use of specialized light emitting devices that may be integrated in to ophthalmic devices.

### BRIEF DESCRIPTION OF THE DRAWINGS

The foregoing and other features and advantages of the disclosure will be apparent from the following, more particular description of preferred embodiments of the disclosure, as illustrated in the accompanying drawings.

FIG. 1 illustrates an exemplary ophthalmic device comprising a sensor system in accordance with some embodiments of the present disclosure.

FIG. 2 illustrates an exemplary ophthalmic device comprising a sensor system in accordance with some embodiments of the present disclosure.

FIG. 3 is a graphical representation demonstrating correlations between measurable electrical parameters and the eye's desired focal length in accordance with the present disclosure.

FIG. 4 is a planar view of an ophthalmic device comprising electronic components, including a sensor system and a variable-optic element in accordance with the present disclosure.

FIG. 5A is a diagrammatic representation of an exemplary electronic system incorporated into an ophthalmic device in accordance with the present disclosure.

FIG. 5B is an enlarged view of the exemplary electronic system of FIG. 5A.

FIG. 6 shows an example spatial configuration of a transceiver.

FIG. 7 shows another example spatial configuration of a transceiver.

FIG. 8 shows another example spatial configuration of a transceiver.

FIG. 9 illustrates an exemplary ophthalmic device.

FIG. 10 is a circuit diagram of an example charge pump incorporated into an ophthalmic device in accordance with the present disclosure.

FIG. 11 is a circuit diagram illustrating a switching configuration of a driving circuit.

FIG. 12A shows a graph of switching waveforms for an example RSID Light Emitter.

FIG. 12B shows a graph of switching waveforms for an example OLED Light Emitter.

FIG. 13 is a circuit diagram illustrating an example driving circuit with a resistive level shifter.

FIG. 14 is a circuit diagram illustrating an example driving circuit with a floating level shifter.

FIG. 15 is a circuit diagram illustrating an example H-Bridge of a driving circuit.

FIG. 16 is a circuit diagram illustrating an example H-Bridge with level shifters of a driving circuit.

FIG. 17 is a graph of example waveforms for operation of an example reverse-biased silicon diode.

FIG. 18A is a circuit diagram illustrating an example photonic receiver.

FIG. 18B is a graph illustration operation of the example photonic receiver.

FIG. 19A is a circuit diagram illustrating an example photonic receiver with a silicon-avalanche photodiode.

FIG. 19B is a graph illustrating operation of the example photonic receiver with the silicon-avalanche photodiode.

FIG. 20 is illustrates an example trans-impedance amplifier incorporated into an ophthalmic device in accordance with the present disclosure.

FIG. 21 is a graph illustrating a transfer function representing a change in voltage output of integrator feedback circuitry.

FIG. 22 shows an example ophthalmic device comprising a photonic transmitter and/or photonic receiver.

FIG. 23 shows an example light-emitting transistor.

FIG. 24 shows an example light-emitting transistor with a driving circuit.

FIG. 25 is a graph illustrating operation of the example light-emitting transistor.

FIG. 26 shows an example light-emitting device positioned to emit light towards an eye of the user.

### DETAILED DESCRIPTION OF THE PREFERRED EMBODIMENTS

Ophthalmic devices may include wearable lenses (including contact lenses) and/or implantable lenses (including intraocular lenses (IOLs)). As an example, conventional contact lenses are polymeric structures with specific shapes to correct various vision problems as briefly set forth above. To achieve enhanced functionality, various circuits and components may be integrated into these polymeric structures. For example, control circuits, microprocessors, communication devices, power supplies, sensors, actuators, light-emitting diodes, and miniature antennas may be integrated into contact lenses via custom-built optoelectronic components to not only correct vision, but to enhance vision as well as provide additional functionality as is explained herein. Electronic and/or powered ophthalmic devices may be designed to provide enhanced vision via zoom-in and zoom-out capabilities, or just simply modifying the refractive capabilities of the lenses. Electronic and/or powered ophthalmic devices may be designed to enhance color and resolution, to display textural information, to translate speech into captions in real time, to offer visual cues from a navigation system, and to provide image processing and internet access. The lenses may be designed to allow the wearer to see in low light conditions. The properly designed electronics and/or arrangement of electronics on lenses may allow for projecting an image onto the retina, for example, without a variable focus optic lens, provide novelty image displays and even provide wakeup alerts.

Alternately, or in addition to any of these functions or similar functions, the contact lenses may incorporate components for the noninvasive monitoring of the wearer's biomarkers and health indicators. For example, sensors built into the lenses may allow a diabetic patient to keep tabs on blood sugar levels by analyzing components of the tear film without the need for drawing blood. In addition, an appropriately configured lens may incorporate sensors for monitoring cholesterol, sodium, and potassium levels, as well as other biological markers. This coupled with a wireless data transmitter could allow a physician to have almost immediate access to a patient's blood chemistry without the need for the patient to waste time getting to a laboratory and having blood drawn. In addition, sensors built into the lenses may be utilized to detect light incident on the eye to compensate for ambient light conditions or for use in determining blink patterns. However, once these sensors collect information, the collected information may need to be transmitted (offloaded) from the ophthalmic devices. As described herein, a transmitter, such as a light source configured to transmit optical communication signals, may be configured to transmit information from the ophthalmic device to a receiver spaced from the ophthalmic device.

The powered or electronic ophthalmic devices of the present disclosure may comprise the necessary elements to correct and/or enhance the vision of patients with one or more of the above described vision defects or otherwise perform a useful ophthalmic function. Alternatively or additionally, the electronic ophthalmic devices may be utilized simply to enhance normal vision or provide a wide variety of functionality as described above. The electronic ophthalmic devices may comprise a variable focus optic lens, an assembled front optic embedded into a contact lens or just simply embedding electronics without a lens for any suitable functionality. The electronic ophthalmic devices of the present disclosure may be incorporated into any number of lenses as described above. In addition, intraocular lenses may also incorporate the various components and functionality described herein.

The present disclosure may be employed in powered ophthalmic devices such as ophthalmic lens or powered ophthalmic device comprising an electronic system, which may be configured to actuate a variable-focus optic or any other device or devices configured to implement any number of numerous functions that may be performed. The electronic system includes one or more batteries or other power sources, power management circuitry, one or more sensors, clock generation circuitry, control algorithms and circuitry, lens driver circuitry, and a light source configured to transmit optical communication signals outwardly from the ophthalmic device. The complexity of these components may vary depending on the required or desired functionality of the lens.

Control of an ophthalmic device may be accomplished through a manually operated external device that communicates with the lens, such as a hand-held remote unit. For example, a fob may wirelessly communicate with the powered ophthalmic device based upon manual input from the wearer. Alternately, control of the powered ophthalmic device may be accomplished via feedback or control signals directly from the wearer. For example, sensors built into the lens may sense signals indicative of ciliary muscle movement, i.e. contraction and relaxation, to compensate for crystalline lens dysfunction or any other problems associated with visual acuity or eye disease. Based upon these signals, the powered ophthalmic devices may change state, for example, its refractive power, in order to either focus on a near object or a distant object. The ciliary muscle in the eye is the structure that controls or attempts to control the shape of the crystalline lens. The crystalline lens is encased in the capsule which is suspended by zonules connected to the ciliary muscle. The ciliary muscle causes the zonules to contract or to relax thereby changing the shape and/or focusing power of the crystalline lens. If the crystalline is unable to partially or fully respond to ciliary muscle movement, the individual will be unable to accommodate, a disease state known as presbyopia. Therefore, a powered or electronic ophthalmic device that responds to these same signals may be utilized to compensate for this loss of ability to accommodate.

The iris, or colored part of the eye, is the partition between the anterior and posterior chambers of the eye and it is made up of two muscles that regulate the size of the pupil to control the amount of light entering the eye. The dilator muscle opens the pupil and the sphincter muscle closes the pupil. The eye also has six extraocular muscles that control the overall movement of the eye or eye globe. The sensing of the extraocular muscles and/or the dilator and sphincter muscles may provide other or additional functionality for a powered or electronic ophthalmic lens. The eye comprises a number of liquid components, including the tear film. These liquids are excellent conductors of electrical signals as well as other signals, such as acoustic signals or sound waves. Accordingly, it should be understood that a neuromuscular sensor in accordance with the present disclosure may provide feedback signals for controlling any number of functions that may be implemented by a powered or electronic ophthalmic lens. However, in accordance with the present disclosure, the circuitry may be configured to detect, isolate and amplify ciliary muscle signals while filtering out noise and other muscle signals. As such, communication signals representing the isolated ciliary muscle signals and/or other characteristics and conditions of the user may be generated and transmitted from (e.g., outwardly) the ophthalmic device. As an example, a receiver may be configured to receive the communication signals and may processes the received communication signals to effect analytics and/or control functions. Such analytics and control may be duplicative of the functions available on the ophthalmic device or may be supplementary to such functions.

A sensor, the components of which may be embedded in a powered ophthalmic device, may detect characteristics of a user, for example, different eye muscle signals. Various signals may include one or more of when an eye is moving up or down, focusing up close, and adjusting to a change in ambient light levels, such as from light to dark, dark to light or any other light condition. The ciliary muscle controls the shape of the crystalline lens in order to focus on a near or distant object. The sensor relies on tracking various signals, including amplitude, time-domain response and frequency composition, produced by or emitted from the ciliary muscle in certain sample conditions, such as when an individual is reading, focusing far away, or in a room with fluorescent lighting. It is important to note that this list of conditions is exemplary and not exhaustive.

These sensor signals may be sampled and/or may be logged and tracked, wherein the various waveforms and frequencies of each of the signals may be distinguished from one or more of other signals, noise, and interference. As set forth above, the circuitry of the present disclosure is preferably designed to detect, isolate and/or filter sensor signals. In alternate embodiments, other characteristic signals may be utilized for augmenting or implementing other ocular functions and may be transmitted from the ophthalmic device. Whenever the sensor detects a recognized signal, it may trigger activity in the electronic circuitry, for example, activating an electronic lens or causing transmission of a communication signal.

There may be various methods used to implement some exemplary embodiments of the present disclosure. For example, sensors may detect a characteristic signal utilizing displacement (e.g., vibration) sensing, impedance sensing, capacitance sensing, temperature sensing, and/or optical sensing, alone or in combination with, one or more of electromyography (EMG), magnetomyography (MMG), phonomyography (PMG), and impedance. Furthermore, sensors may comprise a non-contact sensor, such as an antenna that is embedded into a contact lens, but that does not directly touch the surface of an eye. Alternately, sensors may comprise a contact sensor, such as contact pads that directly touch the surface of an eye. It is important to note that any number of suitable devices and processes may be utilized for the detection of signals from the ciliary muscle as is explained in detail subsequently. As described herein, any type of sensor and/or sensing technology may be utilized.

In certain embodiments, ophthalmic devices may comprise an ophthalmic lens having an optic zone and a peripheral zone. Ophthalmic devices may comprise a variable optic element incorporated into the optic zone of the ophthalmic lens, the variable optic element being configured to change the refractive power of the wearable ophthalmic lens. Ophthalmic devices may comprise a sensor disposed in the peripheral zone of the ophthalmic lens. The sensor may be configured to detect a characteristic of the user and to provide an output. The variable-optic element may be configured to be controlled based at least on the output. A communication signal may be transmitted in response to the output. The communication signal may be representative of at least the output. Additionally or in the alternative, a communication signal may be received. A parameter of the ophthalmic device may be modified based on the received communication signal. The parameter may be associated with the sensor.

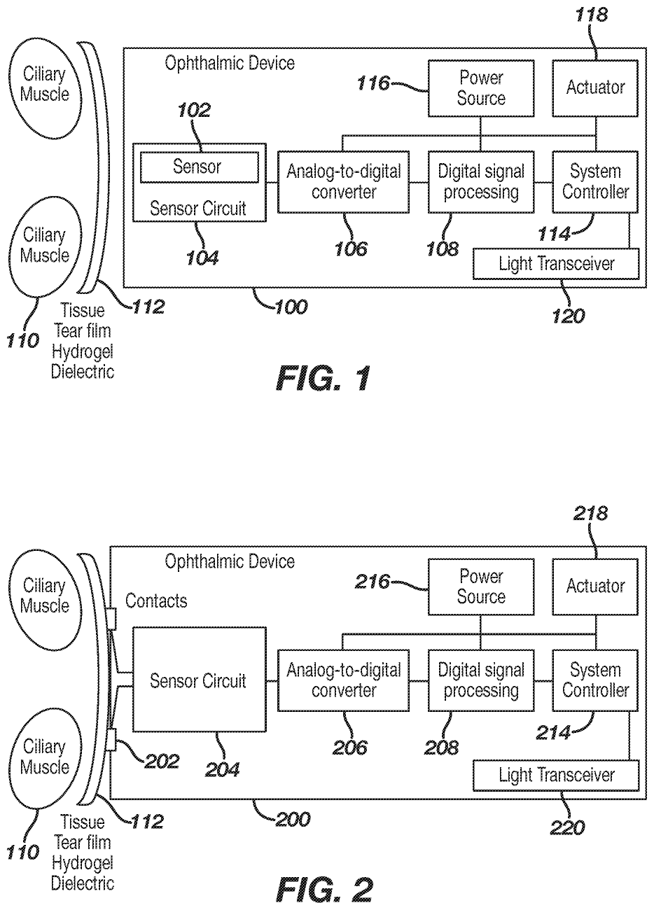

FIG. 1 illustrates, in block diagram form, an ophthalmic device 100 disposed on the front surface of the eye or cornea 112, in accordance with one exemplary embodiment of the present disclosure. Although the ophthalmic device 100 is shown and described as a being disposed on the front surface of the eye, it is understood that other configurations, such as those including intraocular lens configuration may be used. In this exemplary embodiment, the sensor system may comprise one or more of a sensor 102, a sensor circuit 104, an analog-to-digital converter 106, a digital signal processor 108, a power source 116, an actuator 118, a light transceiver 120 (e.g., or more generally a transceiver), and a system controller 114. As illustrated, the ciliary muscle 110 is located behind the front eye surface or cornea 112. More specifically, the globe of the eye can be divided into two segments; namely, the anterior chamber and the posterior chamber. The iris is the partition between the anterior and posterior chambers. Between the front surface of the crystalline lens and the back surface of the iris is the posterior chamber. At the base of the iris is the ciliary body which produces aqueous humor and is continuous with the ciliary muscle. The ophthalmic device 100 is placed onto the front surface of the eye 112 wherein the electronic circuitry of the sensor system may be utilized to implement the neuromuscular sensing of the present disclosure. The sensor 102 as well as the other circuitry is configured to sense signals from ciliary muscle 110 actions through the various tissue and liquids forming the eye and produced by the eye. As set forth above, the various fluids comprising the eye are good conductors of electrical and acoustical signals.

In this exemplary embodiment, the sensor 102 may be at least partially embedded into the ophthalmic device 100. The sensor 102 may be in mechanical communication with the eye, for example disposed to sense vibration associated with (e.g., translating through) the eye. The sensor 102 may be or comprise one or more components configured to sense a displacement (e.g., vibration), impedance, capacitance, or other property at or near the eye. The sensor 102 may comprise a micro ball sensor, a piezo vibration sensor, a cantilever sensor, and the like. The sensor may comprise an impedance or capacitance sensing circuit. The sensor 102 may be configured to generate an electrical signal indicative of the sensed characteristic. As such, when characteristics of the user change, the sensor 102 may sense such change and may generate the electrical signal indicative of such change or resultant characteristic. For example, there may be various signals detected by the sensor 102 depending on the state that a ciliary muscle is in, such as whether it is contracting or relaxing, or on the type of action that a ciliary muscle is trying to perform, such as causing the eye to focus on a near object or a far object. As a further example, particular states of the ciliary muscle representing one or more characteristics of the ciliary muscle at a given time, may be associated with a particular characteristic signature indicative of the particular state. Additionally or alternatively, the change between states of the ciliary muscle may be associated with a particular characteristic signature indicative of the particular transition between states. A set of characteristic signatures may be determined (e.g., via experimentation) and may be stored for subsequent comparison.

In this exemplary embodiment, the sensor 102 may be or comprise one or more electrodes configured to sense a capacitance and/or a change in capacitance as the conditions of the eye and/or eyelid change. For example, various portions of the electrodes comprised by the sensor 102 may be in proximity to the eyelids of the user. The sensor 102 may be configured to provide a measurable capacitance. As such, when the position of the upper eyelid and/or the lower eyelid, relative to the sensor 102, changes, the measurable capacitance may change. Therefore, various capacitance signals may be used to represent positions of the eyelids, which may operate as a representation of eye position and/or eye gaze.

The sensor circuit 104 or sensor system may be configured to process signals received by the sensor 102. As an example, the sensor circuit 104 may be configured to amplify a signal to facilitate integration of small changes in signal level. As a further example, the sensor circuit 104 may be configured to amplify a signal to a useable level for the remainder of the system, such as giving a signal enough power to be acquired by various components of the sensor circuit 104 and/or the analog-to-digital converter 106. In addition to providing gain, the sensor circuit 104 may include other analog signal conditioning circuitry such as filtering and impedance matching circuitry appropriate to the sensor 102 and sensor circuit 104 output. The sensor circuit 104 may comprise any suitable device for amplifying and conditioning the signal output by the sensor 102. For example, the sensor circuit 104 may simply comprise a single operational amplifier or a more complicated circuit comprising one or more operational amplifiers.

As set forth above, the sensor 102 and the sensor circuit 104 are configured to capture and isolate the signals indicative of characteristic of the ciliary muscle from the noise and other signals produced in or by the eye and convert it to a signal usable ultimately by the system controller 114. The system controller 114 is preferably preprogrammed to recognize the various signals produced by the ciliary muscle under various conditions and provide an appropriate output signal to the actuator 118.

In this exemplary embodiment, the analog-to-digital converter 106 may be used to convert an analog signal output from the amplifier into a digital signal for processing. For example, the analog-to-digital converter 106 may convert an analog signal output from the sensor circuit 104 into a digital signal that may be useable by subsequent or downstream circuits, such as a digital signal processing system 108 or microprocessor. A digital signal processing system or digital signal processor 108 may be utilized for digital signal processing, including one or more of filtering, processing, detecting, and otherwise manipulating/processing sampled data to discern a characteristic signal from noise and interference. The digital signal processor 108 may be preprogrammed with the ciliary muscle responses described above. The digital signal processor 108 may be implemented utilizing analog circuitry, digital circuitry, software and/or preferably a combination thereof. For example, various ciliary muscle signals that may occur within a certain frequency range may be distinguishable from other signals, noise, and interference that occur within other frequency ranges. Certain commonly occurring noise and interference signals may be notched at various stages in the signal acquisition chain utilizing analog or digital filters, for example, harmonics of 50/60 Hz AC mains and fluorescent lights.

A power source 116 supplies power for numerous components comprising the non-contact sensor system. The power may be supplied from a battery, energy harvester, or other suitable means as is known to one of ordinary skill in the art. Essentially, any type of power source may be utilized to provide reliable power for all other components of the system. A characteristic signal, processed from analog to digital, may enable activation of the system controller 114. Furthermore, the system controller 114 may control other aspects of a powered ophthalmic device depending on input from the digital signal processor 108, for example, changing the focus or refractive power of an electronically controlled lens through an actuator 118. Additionally or alternatively, the system controller 114 may be configured to control a transmission of information from the ophthalmic device, for example via the light transceiver 120.

In further alternate exemplary embodiments, the system controller 114 may receive input from sources including one or more of a contact sensor, a blink detector, and a fob control. By way of generalization, it may be obvious to one skilled in the art that the method of activating and/or controlling the system controller 114 may require the use of one or more activation methods. For example, an electronic or powered ophthalmic device may be programmable specific to an individual user, such as programming a lens to recognize both of an individual's ciliary muscle signals when performing various actions, for example, focusing on an object far away, or focusing on an object that is near, and an individual's blink patterns. In some exemplary embodiments, using more than one method to activate an electronic ophthalmic device, such as ciliary muscle signal detection and blink detection, may give the ability for each method to crosscheck with another before activation of the contact lens occurs. An advantage of crosschecking may include mitigation of false positives, such as minimizing the chance of unintentionally triggering a lens to activate.

In one exemplary embodiment, the crosschecking may involve a voting scheme, wherein a certain number of conditions are met prior to any action taking place. The actuator 118 may comprise any suitable device for implementing a specific action based upon a received command signal. The actuator 118 may comprise an electrical device, a mechanical device, a magnetic device or any combination thereof. The actuator 118 receives a signal from the system controller 114 in addition to power from the power source 116 and produces some action based on the signal from the system controller 114. For example, if the system controller 114 signal is indicative of the wearer trying to focus on a near object, the actuator 118 may be utilized to somehow change the refractive power of the electronic ophthalmic lens.

The light transceiver 120 may be or comprise any device configured to effect the transmission of a signal such as an optical signal (e.g., light signal) and/or receive a transmission of a signal, such as an optical signal. The light transceiver 120 may be or comprise a light-emitting device. The light transceiver 120 may be or comprise a light detection device. The light transceiver 120 may comprise a driver circuit configured to control the selective energizing of the light-emitting device. As explained in further detail herein, the light-emitting device may comprise a reverse-biased silicon diode (RSiD), an electro-luminescent device (ELD), and/or an organic LED (OLED). The light detection device may comprise a reverse-biased diode, a silicon avalanche photodiode, and/or the like.

FIG. 2 illustrates an ophthalmic device 200, comprising a sensor system, shown on the front surface of the eye or cornea 112 in accordance with another exemplary embodiment of the present disclosure. In this exemplary embodiment, a sensor system may comprise a contact or multiple contacts 202, a sensor circuit 204, an analog-to-digital converter 206, a digital signal processor 208, a power source 216, an actuator 218, a light transceiver 220, and a system controller 214. The ciliary muscle 110 is located behind the front eye surface or cornea 112. The ophthalmic device 200 is placed onto the front surface of the eye 112, such that the electronic circuitry of the sensor may be utilized to implement the neuromuscular sensing of the present disclosure. The components of this exemplary system are similar to and perform the same functions as those illustrated in FIG. 1, with the exception of contacts 202 and the sensor circuit 204. In other words, since direct contacts 202 are utilized, there is no need for an antenna or an amplifier to amplify and condition the signal received by the antenna.

In the illustrated exemplary embodiment, the contacts 202 may provide for a direct electrical connection to the tear film and the eye surface. For example, the contacts 202 may be implemented as metal contacts that are exposed on the back curve of the ophthalmic device 200 and be made of biocompatible conductive materials, such as gold or titanium. Furthermore, the contact lens polymer may be molded around the contacts 202, which may aid in comfort on the eye and provide improved conductivity through the ophthalmic device 200. Additionally, the contacts 202 may provide for a low resistance connection between the eye's surface 112 and the electronic circuitry within the ophthalmic device 200. Four-terminal sensing, also known as Kelvin sensing, may be utilized to mitigate contact resistance effects on the eye. The sensor circuit 204 may emit a signal with several constituent frequencies or a frequency sweep, while measuring the voltage/current across the contacts 202.

In an alternate exemplary embodiment, the sensor circuit 204 may be configured to sense a characteristic (e.g., vibration, impedance, capacitance, temperature, etc.) produced by a user such as via the contraction or relaxation of the ciliary muscle 110. It is important to note that various types of sensors may be utilized, given that the eye comprises various fluids, including tears which are excellent conductors. The sensor circuit 204 may be configured to measure various characteristics. In this exemplary embodiment, the analog-to-digital converter 206 and the digital signal processing 208 may be configured differently for a contact-based sensor as opposed to a non-contact based sensor, as described in FIG. 1. For example, there may be a different sample rate, a different resolution, and different signal processing algorithm 208. As such, the light transceiver 220 may be configured to transmit communication signals indicative of the various sensed characteristics. The light transceiver 220 may be or comprise a light-emitting device configured to generate and transmit an optical communication signal. The light transceiver 220 may comprise a light-emitting diode and a driver to selectively energize the diode. Other configurations of generating and transmitting the communication signal may be used.

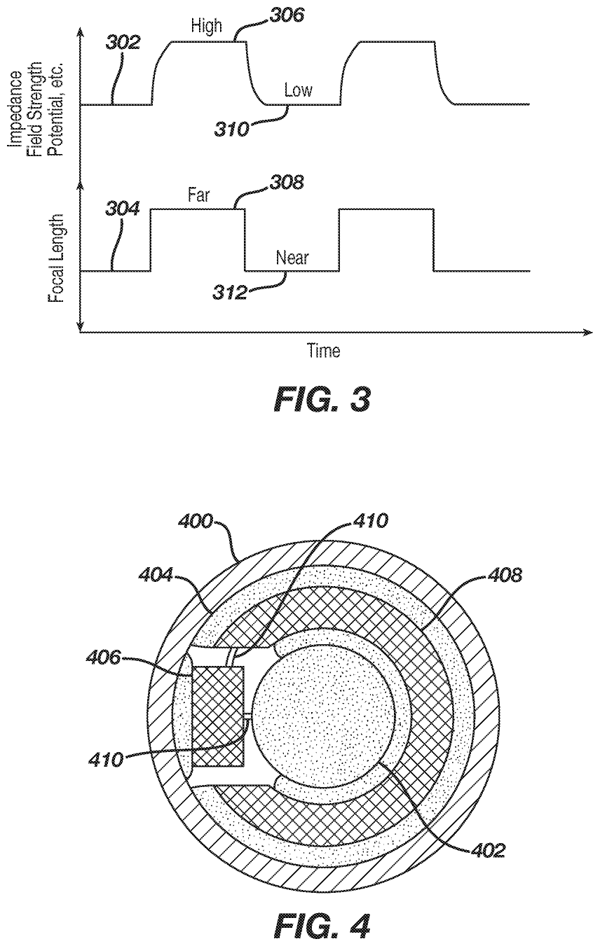

FIG. 3 illustrates a graph demonstrating exemplary correlations between measurable electrical parameters and the eye's focal length as described in the referenced literature. Trace 302 is a representation of an electrically measurable signal in or on the eye. For example, such signals may be detected as one or more of impedance, voltage potential, induced electromagnetic field, and other measurable parameters (e.g., displacement). Trace 304 is a representation of a desired focal length wherein for example, if clinical subjects focused on objects at 0.2 and 2.0 meter distances, the ciliary muscle may undergo a corresponding change in measurable electrical parameters and displacement characteristics accordingly, depending on the distance of focus. However, using the same example, the actual focal length of a lens may not change or only changes minimally, such as in cases where a person may be presbyopic and the lens of the eye is too rigid and unable to accommodate for a change in focus, even where the ciliary muscles are responding to the change.

As described in the literature, there is a correlation between a measurable electrical signal and a focal length. As illustrated in FIG. 3, impedance is high 306 when the focal length is far 308 and impedance is low 310 when the focal length is near 312. Additionally, as described in the literature but not illustrated in FIG. 3, a correlation exists between the amplitude of traces 302 and 304 for intermediate values. Moreover, displacement signatures may be associated (e.g., correlated) with a particular state of the ciliary muscle, which may also be associated with an impedance.

In some exemplary embodiments, characteristics of an electrical signal (e.g., trace 302, 304) such as shape, frequency content, timing, and amplitude, may vary due to several factors including one or more of a detection method utilized (e.g., vibration, impedance, or field strength), an individual's eye physiology, ciliary muscle fatigue, electrolyte levels in the eye, state of presbyopia, interference, and focal length. For example, depending on the type of detection method used, the correlation between desired focus and measurable electrical parameter may have the opposite polarity from what is illustrated in FIG. 3.

Additionally, for example, a signal may be distorted from carrying one or more of significant noise, interference from other muscles, and interference from various environmental sources or due to the effects of aging, disease or genetics. Accordingly, studies of eye response and individual user measurement and training may be used to program the digital signal circuitry to properly detect the eye's desired focal length. Parameters of the digital signal processing may be adjusted in response to other measurements, for example, time of day, measured electrolyte levels, ambient light levels and the like. Furthermore, recorded samples of a user's eye focus signals may be used in conjunction with interference detection and mitigation techniques. It is important to note that any type of sensor may be utilized in accordance with the present disclosure. As long as there is muscle movement associated with changing conditions, it may be sensed, processed and utilized to enhance, augment or simply provide vision correction. Additionally or alternatively, recorded samples of a user's eye focus signals may be transmitted to a receiver external to the eye and may be used in conjunction with interference detection and mitigation techniques to provide additional analytics and control external to the ophthalmic device and eye.

Referring now to FIG. 4, there is illustrated, in planar view, a wearable electronic ophthalmic device comprising a sensor in accordance with the present disclosure. The ophthalmic device 400 comprises an optic zone 402 and a peripheral zone 404. The optic zone 402 may function to provide one or more of vision correction, vision enhancement, other vision-related functionality, mechanical support, or even a void to permit clear vision. In accordance with the present disclosure, the optic zone 402 may comprise a variable optic element configured to provide enhanced vision at near and distant ranges based on signals sensed from the ciliary muscle. The variable-optic element may comprise any suitable device for changing the focal length of the lens or the refractive power of the lens based upon activation signals from the sensing system described herein. For example, the variable optic element may be as simple as a piece of optical grade plastic incorporated into the lens with the ability to have its spherical curvature changed. The peripheral zone 404 comprises one or more of electrical circuits 406, a power source 408, electrical interconnects 410, mechanical support, as well as other functional elements.

The electrical circuits 406 may comprise one or more integrated circuit die, printed electronic circuits, electrical interconnects, and/or any other suitable devices, including the sensing circuitry described herein. The power source 408 may comprise one or more of battery, energy harvesting, and or any other suitable energy storage or generation devices. It is readily apparent to the skilled artisan that FIG. 4 only represents one exemplary embodiment of an electronic ophthalmic lens and other geometrical arrangements beyond those illustrated may be utilized to optimize area, volume, functionality, runtime, shelf life as well as other design parameters. It is important to note that with any type of variable optic, the fail-safe is distance vision. For example, if power were to be lost or if the electronics fail, the wearer is left with an optic that allows for distance vision.

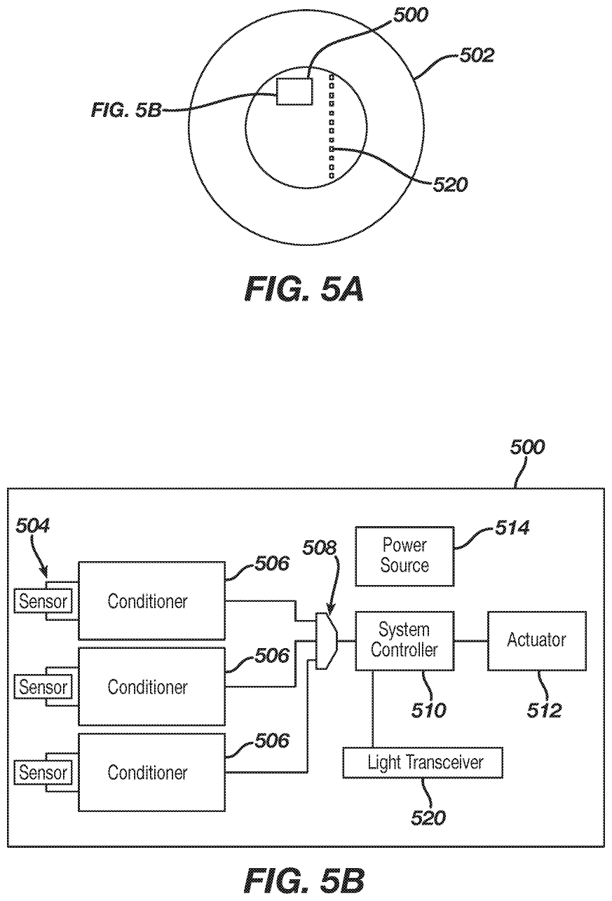

FIGS. 5A and 5B illustrate an alternate exemplary sensor system 500 incorporated into an ophthalmic device 502 such as a contact lens. FIG. 5A shows the system 500 on the device 502 and FIG. 5B shows an exemplary schematic view of the system 500. In this exemplary embodiment, sensors 504 may be used to sense a characteristic at and/or adjacent an eye of the user of the ophthalmic device 502. As an example, the sensors 504 may be configured to detect a displacement or impedance that may be affected by a configuration of the ciliary muscle of the user. As another example, the sensors 504 may be configured to sense a capacitance, for example, affected by a position of the eyelids of a user. As a further example, the sensors 504 may be configured to sense a temperature. As shown, the sensor system 500 may comprise one or more transceivers 520 configured to cause transmission of a signal (e.g., communication signal) and/or receive transmission of a signal. For example, the transceiver 520 may be an optical transmitter comprising one or more light-emitting devices configured to selectively transmit an optical signal. For example, the transceiver 520 may be an optical receiver comprising one or more light-detecting devices configured to selectively detect an optical signal.

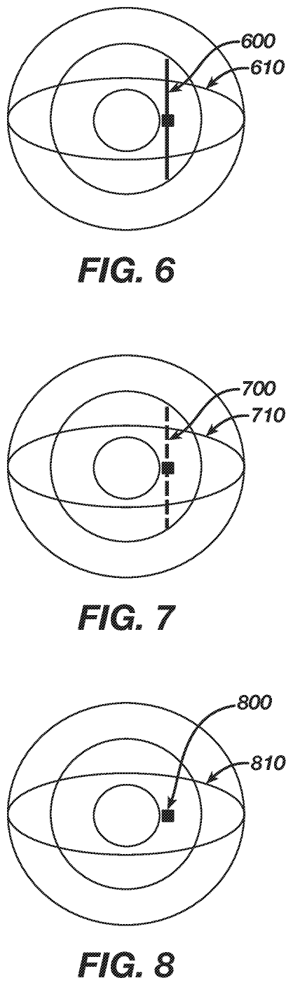

One or more of the devices (e.g., light-emitting devices, light-detection devices) of the transceiver 520 may be configured in a linear configuration 600 (FIG. 6), a segmented configuration 700 (FIG. 7), and/or a point configuration 800 (FIG. 8). In the various configurations illustrated in FIGS. 6-8, the transceivers in the various configurations 600, 700, 800 may be used to transmit an optical signal from the ophthalmic device (e.g., outwardly from the eye) and/or receive an optical signal at the ophthalmic device.

Returning to FIGS. 5A and 5B, sensor conditioners 506 create an output signal indicative of a measurement of one or more sensors 504 in communication with a respective one or more of the sensor conditioners 506. For example, the sensor conditioners may amplify and or filter a signal received from a respective sensor 504. The output of the sensor conditioners 506 may be combined with a multiplexer 508 to reduce downstream circuitry.

In certain embodiments, downstream circuitry may include a system controller 510, which may comprise an analog-to-digital converter (ADC) that may be used to convert a continuous, analog signal into a sampled, digital signal appropriate for further signal processing. For example, the ADC may convert an analog signal into a digital signal that may be useable by subsequent or downstream circuits, such as a digital signal processing system or microprocessor, which may be part of the system controller 510 circuit. A digital signal processing system or digital signal processor may be utilized for digital signal processing, including one or more of filtering, processing, detecting, and otherwise manipulating/processing sampled data. The digital signal processor may be preprogrammed with various characteristic signatures. As an example, a data store of characteristic measurements or signatures may be mapped to particular configurations of the ciliary muscle and/or other conditions relating to the user. As such, when sensor measurements matching or near a particular signature are detected, the associated characteristic or condition may be extrapolated. Although reference is made to the ciliary muscle configuration, other conditions relating to the eye may be extrapolated such as gaze and/or accommodation. The digital signal processor also comprises associated memory. The digital signal processor may be implemented utilizing analog circuitry, digital circuitry, software, and/or preferably a combination thereof.

The system controller 510 receives inputs from the sensor conditioner 506 via a multiplexer 508, for example, by activating each sensor 504 in order and recording the values. It may then compare measured values to pre-programmed patterns and historical samples to determine a condition or characteristic of the user. It may then activate a function in an actuator 512, for example, causing a variable-focus lens to change to a closer focal distance. The sensors 504, and/or the whole electronic system, may be encapsulated and insulated from the saline contact lens environment. Various configurations of the sensors 504 may facilitate optimal sensing conditions as the ophthalmic device 502 shifts or rotates.

A power source 514 supplies power for numerous components comprising the lid position sensor system 500. The power source 514 may also be utilized to supply power to other devices on the contact lens. The power may be supplied from a battery, energy harvester, or other suitable means as is known to one of ordinary skill in the art. Essentially, any type of power source 514 may be utilized to provide reliable power for all other components of the system. A vibration sensor array pattern, processed from analog to digital, may enable activation of the system controller 510 or a portion of the system controller 510. Furthermore, the system controller 510 may control other aspects of a powered ophthalmic device depending on input from the multiplexer 508, for example, changing the focus or refractive power of an electronically controlled lens through the actuator 512.

In one exemplary embodiment, the electronics and electronic interconnections are made in the peripheral zone of a contact lens rather than in the optic zone. In accordance with an alternate exemplary embodiment, it is important to note that the positioning of the electronics need not be limited to the peripheral zone of the contact lens. For example, a light-emitting device configured to emit light towards an eye of the user (e.g., used as an alert signal) may be positioned in the optic zone of the contact lens. The light-emitting device may be positioned a threshold distance from the retina. For example, if the device or feature is too close to the eye the retina will not be able to focus on it. For example, calibration marks and alignment structures may be clearly in the optic zone of the lens but may not be visible to the user because the structures are too far inside the eyes focal range.

All of the electronic components described herein may be fabricated utilizing thin film technology and/or transparent materials. If these technologies are utilized, the electronic components may be placed in any suitable location as long as they are compatible with the optics. The activities of the digital signal processing block and system controller (system controller 510 in FIG. 5B) depend on the available sensor inputs, the environment, and user reactions. The inputs, reactions, and decision thresholds may be determined from one or more of ophthalmic research, pre-programming, training, and adaptive/learning algorithms. For example, the general characteristics of ciliary muscle configuration may be well-documented in literature, applicable to a broad population of users, and pre-programmed into system controller. However, an individual's deviations from the general expected response may be recorded in a training session or part of an adaptive/learning algorithm which continues to refine the response in operation of the electronic ophthalmic device. In one exemplary embodiment, the user may train the device by activating a handheld fob, which communicates with the device, when the user desires near focus. A learning algorithm in the device may then reference sensor inputs in memory before and after the fob signal to refine internal decision algorithms. This training period could last for one day, after which the device would operate autonomously with only sensor inputs and not require the fob.

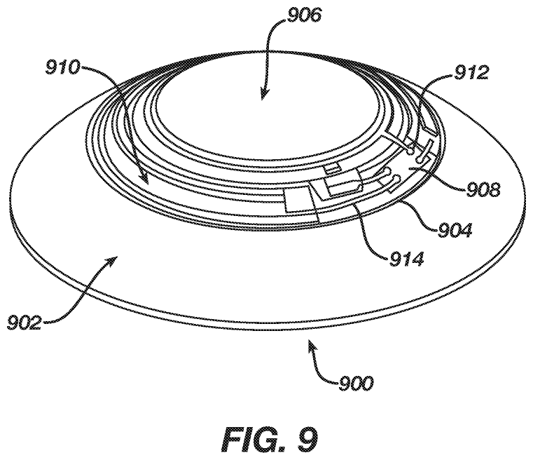

FIG. 9 is a diagrammatic representation of an exemplary electronic insert, including a combined blink detection and communication system, positioned in a powered or electronic ophthalmic device in accordance with the present disclosure. As shown, a contact lens 900 comprises a soft plastic portion 902 which comprises an electronic insert 904. This insert 904 includes a lens 906 which is activated by the electronics, for example, focusing near or far depending on activation. Integrated circuit 908 mounts onto the insert 904 and connects to batteries 910, lens 906, and other components as necessary for the system. The integrated circuit 908 includes a sensor 912 and associated signal path circuits. The sensor 912 may comprise any sensor configuration such as those described herein. The sensor 912 may also be implemented as a separate device mounted on the insert 904 and connected with wiring traces 914.

In accordance with one exemplary embodiment, a digital communication system comprises a number of elements which when implemented, may take on any number of forms. The digital communication system generally comprises an information source, a source encoder, a channel encoder, a digital modulator, a channel, a digital demodulator, a channel decoder and a source decoder. The information source may comprise any device that generates information and/or data that is required by another device or system. The source may be analog or digital. If the source is analog, its output is converted into a digital signal comprising a binary string. The source encoder implements a process of efficiently converting the signal from the source into a sequence of binary digits. The information from the source encoder is then passed into a channel encoder where redundancy is introduced into the binary information sequence. This redundancy may be utilized at the receiver to overcome the effects of noise, interference and the like encountered on the channel. The binary sequence is then passed to a digital modulator which in turn converts the sequence into analog electrical signals for transmission over the channel. Essentially, the digital modulator maps the binary sequences into signal waveforms or symbols. Each symbol may represent the value of one or more bits. The digital modulator may modulate a phase, frequency or amplitude of a high frequency carrier signal appropriate for transmission over or through the channel. The channel is the medium through which the waveforms travel, and the channel may introduce interference or other corruption of the waveforms. In the case of the wireless communication system, the channel is the atmosphere. The digital demodulator receives the channel-corrupted waveform, processes it and reduces the waveform to a sequence of numbers that represent, as nearly as possible, the transmitted data symbols. The channel decoder reconstructs the original information sequence from knowledge of the code utilized by the channel encoder and the redundancy in the received data. The source decoder decodes the sequence from knowledge of the encoding algorithm, wherein the output thereof is representative of the source information signal. It is important to note that the above described elements may be realized in hardware, in software or in a combination of hardware and software. In addition, the communication channel may comprise any type of channel, including wired and wireless. In wireless, the channel may be configured for high frequency electromagnetic signals, low frequency electromagnetic signals, visible light signals and infrared light signals.

The activities of the acquisition sampling signal processing block and system controller depend on the available sensor inputs, the environment, and user reactions. The inputs, reactions, and decision thresholds may be determined from one or more of ophthalmic research, preprogramming, training, and adaptive/learning algorithms. For example, the general characteristics of eye movement may be well-documented in literature, applicable to a broad population of users, and pre-programmed into system controller. However, an individual's deviations from the general expected response may be recorded in a training session or part of an adaptive/learning algorithm which continues to refine the response in operation of the electronic ophthalmic device. In one exemplary embodiment, the user may train the device by activating a handheld fob, which communicates with the device, when the user desires near focus. A learning algorithm in the device may then reference sensor inputs in memory before and after the fob signal to refine internal decision algorithms. This training period could last for one day, after which the device would operate autonomously with only sensor inputs and not require the fob. An intraocular lens or IOL is a lens that is implanted in the eye and replaces the crystalline lens. It may be utilized for individuals with cataracts or simply to treat various refractive errors. An IOL typically comprises a small plastic lens with plastic side struts called haptics to hold the lens in position within the capsular bag in the eye. Any of the electronics and/or components described herein may be incorporated into IOLs in a manner similar to that of contact lenses.

Communications systems that are operational during normal use and wear may be configured for wireless communication. There are three main wireless modes of communication that are available; Radio frequency (RF), Ultrasonic and Photonic. Photonic systems have been identified as potential candidates for powered ophthalmic device communication systems. An example photonic transceiver may comprise of a light-emitter and/or a photodetector. Photodetectors can efficiently and inexpensively be implemented in silicon integrated circuits (ICs). The most common light-emitting devices, light-emitting diodes (LEDS) and semiconductor lasers (SEML), are not typically available in silicon IC technology. LEDs and SEMLs are typically built in specialized semiconductor processes which use III-V compounds, direct band gap semiconductors, that are more favorable for light creation. These devices cannot be inexpensively implemented into a silicon IC. An example photonic transceiver may be implemented as one or two discrete devices. The one or two discrete devices may be incorporated into or separate from an integrated circuit, such as a silicon based integrated circuit, configured to provide functionality for driving, amplification, modulation, demodulation, and/or the like functions.

The embedded electronics of the ophthalmic device may be disposed in a periphery of the device away from any area that could potentially obscure vision. For example, the embedded electronics may be disposed in a periphery zone 404, as illustrated in FIG. 4. The volume available for implementation may be limited in all dimensions. The volume and part count of commercially available photonic devices are not easily integrated into dimensions that are suitable for the powered ophthalmic lens.

LEDs and SEMLs require a significant amount of current to emit light that is useful for communications. Review of operating characteristic curves show that LEDs and SEMLs consume in the order of 20 mA-100 mA to generate useful light. The voltage requirements for LEDS for white light are above the range targeted for the powered ophthalmic battery. In order to generate light with a typical LED, the battery voltage would have to be multiplied by some electronic means and the battery and multiplication circuitry would have to be able to supply the necessary current for light emission. SEML have lower operating voltage (in the range of the battery) but current requirements in the 60 to 200 mA range. Due to their sizes, batteries for powered ophthalmic lenses have limited capacity and significant internal resistance which limits peak current. Typical operation of an LED or SEML would limit the operating life of a powered ophthalmic lens to levels that would not be useful for most consumer based applications.

To meet the size and battery requirements for the photonic transceiver a combination of alternative light emitters, novel driving techniques for lowering the current consumption, and a selective receiver technique including an alternative photodetector are disclosed below.

Three example light emitters are described to implement an example photonic transmitter. The light emitter may comprise a reverse-biased silicon diode (RSiD), an electro-luminescent device (ELD), an organic LED (OLED), combination thereof, and/or the like. Each of the example light emitters has a property or properties that enable the light emitter to be used as the photonic transmitter of a powered ophthalmic device.

The reverse-biased silicon diode has been shown to emit light when operated in or near the reverse breakdown voltage region. Light is generated by radiating recombination of hot electrons in the high-field region. Various device design techniques can be used to tune the device performance for various operating parameters. A unique feature that makes the RSiD applicable to the powered ophthalmic lens is that the RSiD may be fabricated in the same silicon integrated circuit as other elements of the ophthalmic device, such as communications elements (e.g., wireless transceiver), driving elements (e.g., driving circuits to control the RSiD), and/or photonic receiver circuitry. In this case, separate discrete devices are not required, thus potentially reducing implementation complexity and cost. The volume to implement the RSiD is only marginally increased.

An example ELD may be made of a material that emits light when a high electric field is applied across the device or a large electric current is passed through the ELD. To meet the battery life requirements of the ophthalmic device, only ELD materials that emit light with applied electric field are considered. Typically, the ELD may use one transparent electrode (e.g., made of Indium Tin Oxide, ITO), a phosphor, a second metallic electrode, a combination thereof, and/or the like. The ELD device may be encapsulated. The ELD device may be flexible and be made in a wide variety of shapes and configurations, such as a flat panel, wire, or tape. In an aspect, an example, ELD driver panels may have a thickness of 120 μm. ELDs may operate on a higher voltage AC signal. The ELD may be configured to minimize current consumption. For example, the ELD may be configured to function as a capacitive load to the driving circuitry such that for the voltage mode operation current consumption is minimized. The ELD may be configured to produce an optical signal sufficient for optical communications. For example, an AC signal of about 60Vpp and about 50 Hz may be sufficient to produce illumination for optical communications. As an example, power consumed in a 1 mm² ELD (e.g., ELD panel) may be in the order of 27.9 μW with an operating current of roughly 500 nA. This example current is significantly lower than the mA currents required by typically LED light emitters. The device count for an example transceiver may be reduced to two devices, one ELD for light emission and one silicon integrated circuit. The silicon integrated circuit may comprise a photonic receiver, driving circuitry, and/or communication circuitry. The size, flexibility and cost of the ELD make the ELD an option for integration into the powered ophthalmic device.

OLEDs are LEDs which use a layer of emissive electroluminescent organic material which emits light in response to an applied electric current. OLEDs may be thin film devices. OLEDs may be integrated in the upper metal layers of silicon CMOS processes. Such implementation allows the OLED to be fully integrated into a silicon integrated circuit. The silicon based integrated circuit may comprise a photonic receiver, driving circuitry, and/or communication circuitry. When an OLED is used, separate discrete devices may not be required. The volume to implement the integrated Silicon photonic transducer is only marginally increased. An example OLED may be powered by an applied voltage of about 10V and a current of about 2 mA/um2. An OLED emitter of 0.25 mm2 may utilize a 500 μA of current at 10V to produce light useful for communication.

The use of the light emission devices described herein are novel, unconventional, and improve upon the use of a standard light emission device. Each of the light emission devices described herein may meet the volume requirements of the powered ophthalmic device. Each of the light emission devices may have a lower drain on a battery (e.g., of an ophthalmic device) than a conventional LED or SEML. To operate these light emission devices and meet the battery drain requirements of the ophthalmic device, novel driving circuits and techniques are described. Each light emission device has slightly different operational conditions that is addressed by a generalized approach with appropriate variations.

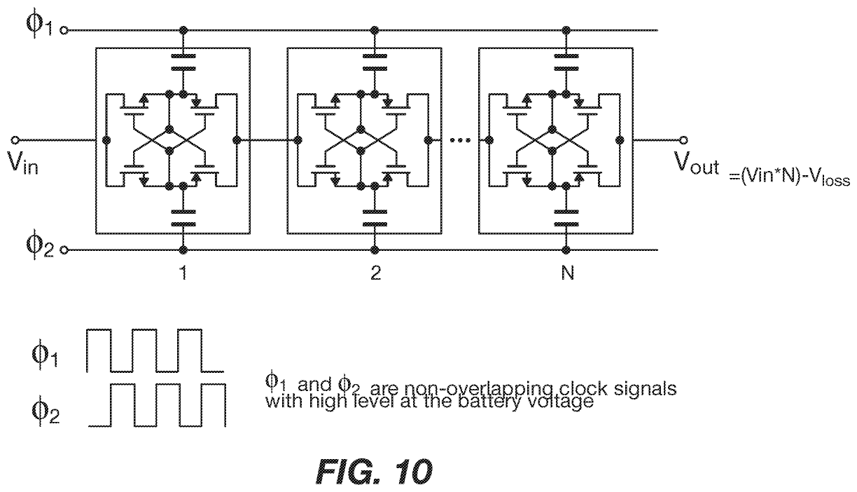

An example first operational condition comprises a condition to generate a voltage that is larger than the battery voltage (Vbatt) of an ophthalmic device. Several circuit techniques are described herein to perform meet the first operational condition. In the case of the ophthalmic device, additional discrete devices are undesirable and may not meet the cost and volume requirements of the application. In an aspect, the light-emitting device may comprise a charge pump. The charge pump may be integrated into a standard high-voltage CMOS process (HVCMOS) to multiply the battery voltage. The HVCMOS process may allow operation of voltages that exceed the battery voltage. This device can be fully integrated into a silicon IC that comprises a receiver and communications functions, minimally impacting the volume and cost requirements of the application. The ophthalmic device may comprise one or more charge pumps described herein. For example, FIG. 10 shows an example charge pump. The example charge pump may comprise cross-coupled CMOS devices which have isolated bodies with a breakdown voltage that allows the charge pump to float above the substrate voltage to the desired output voltage. The charge pump may be configured to multiply a battery voltage. The voltage multiplication may be based on the number of stages times the supply voltage used in switching the capacitor voltages. For example, if the battery were 1.5V, 18 charge pump stages would yield 27 volts minus the losses associated with parasitics and threshold voltages of the transistors. The amount of loss varies between the different architectures of the charge pump.

The example charge pump circuit may be configured to achieve a voltage level sufficient to operate a light-emitting device. For example, a breakdown operation of the RSiD may use 5-9 volts. With a nominal battery voltage of 1.6 volts, a 4-7 stage charge pump may be used to increase the voltage to meet the voltage of the breakdown operation. ELD drivers may use 60V for operation. With the same nominal 1.6-volt battery, a 38-40 stage charge pump may be used with the ELD. The OLED may use 10V for operation. A 7-9 stage charge pump may be used to power the OLED.

Use of the charge pump may yield the necessary voltage level for operation but the charge pump may not have the capability to supply voltage and current necessary for typical CMOS switching operation. To overcome these limitations, the charge pump may be configured to use a reservoir capacitor to act as a reservoir of charge for the current pulse. The capacitor may be charged and discharged through a switching scheme used to deliver current to the light-emitting device (e.g., for a limited pulse duration). Information can be transmitted by the optical communication system by turning the light-emitting device on and off. This technique is commonly known as amplitude modulation. This form of amplitude modulation is referred to as On-Off Key switching (OOK). This technique is used to transmit bursts which encode a state of“1” when the light is on and a state of “0” when the light is off. Additional coding techniques, such as Manchester coding, may be added to the modulation scheme to lower the probability of errors in encoding and decoding information.

Specialized techniques may be used to switch the high-voltage on the reservoir capacitor to the light-emitting device without damaging or degrading the transistors in the CMOS process. The RSiD and the OLED device may be configured to use similar switching techniques. The ELD may be configured to use a switching technique which effectively converts a DC charge pump voltage to an AC voltage.

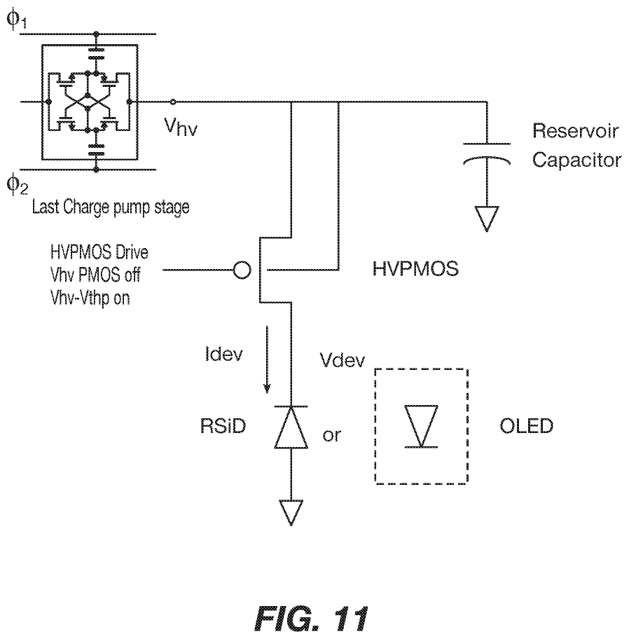

For the RSiD and OLED a HVPMOS device may be used to switch the high-voltage output of the charge pump to the light-emitting device. FIG. 11 shows a schematic of a switching configuration. As an illustration, operation of the circuit may be as follows:
1. The reservoir capacitor at the output of the charge pump may be charged to the desired voltage (greater than the breakdown voltage of the silicon diode for the reverse silicon diode and 10V for the OLED).
2. The last stage of the charge pump may be turned off by disabling ϕ1 and ϕ2.
3. A voltage, at least one HVPMOS threshold voltage (Vₜₕᵥₚ) lower than the charge pump HV output, may be applied to the gate of the HVPMOS device. (e.g., two techniques to drive the PMOS gate are described below). The HVPMOS device is then conducting and connects Vhv to the light-emitting device (e.g., RSiD or OLED)
4. The RSiD junction may break down and draws current (Idev) from the reservoir capacitor. Light is emitted. The OLED has a forward voltage applied and draws current. Light is emitted with forward current and adequate forward voltage.
5. Vhv drops as the capacitor is discharged. Current stops conducting in the RSID when Vhv drops below the breakdown voltage of the device.
6. The OLED continues to conduct current if the HVPMOS device is on. Light ceases emission in the OLED when Vhv drops below the voltage emission level for the OLED used.
7. The gate of the HVPMOS device is switched to Vₕᵥ. The PMOS device is no longer conducting and Vhv is disconnected from the light-emitting device.
8. The charge pump is turned back on to replenish the reservoir capacitor.

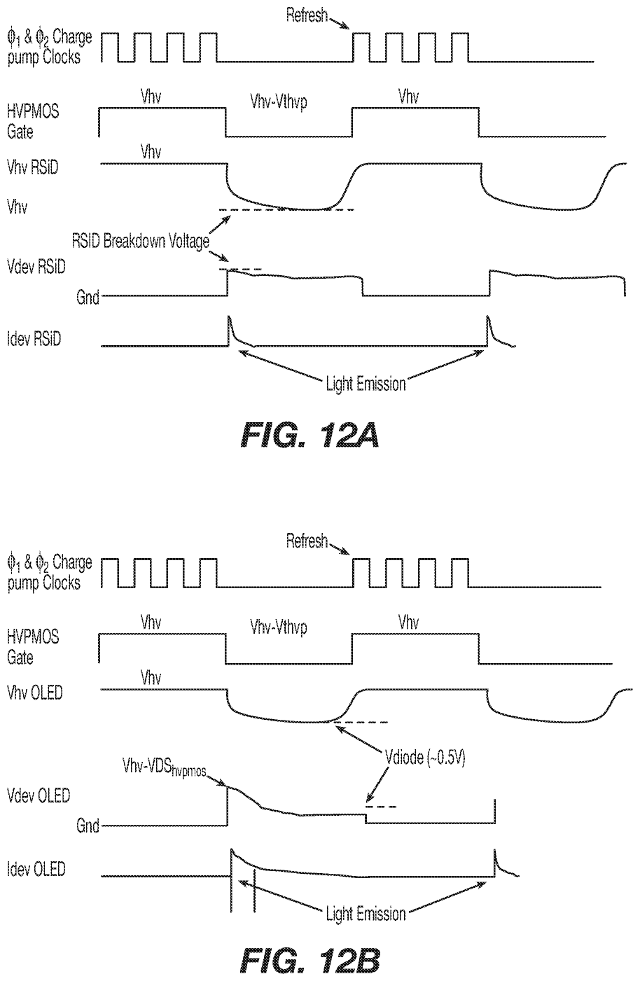

The voltage and current waveforms of the switching operation are shown in FIG. 12A and FIG. 12B. FIG. 12A shows a graph of switching waveforms for the RSID Light Emitter. FIG. 12B shows a graph of switching waveforms for the OLED Light Emitter.

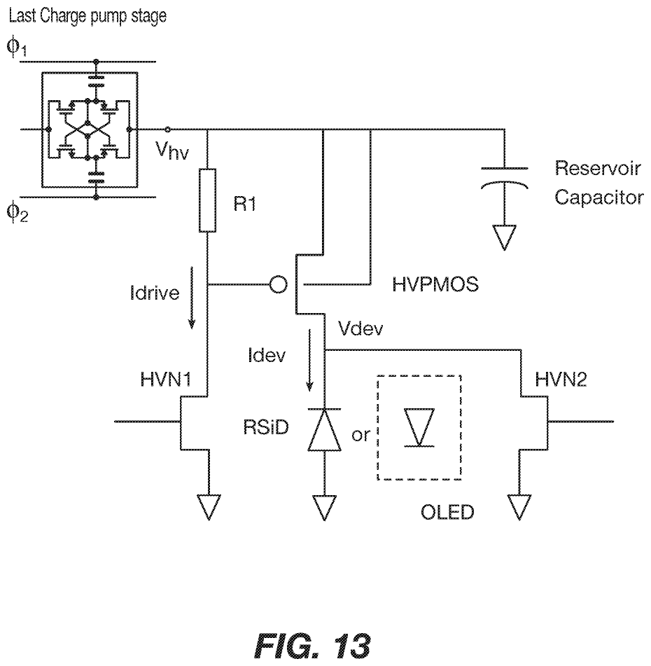

In an aspect, the ophthalmic device may comprise one or more gate circuits. The gate circuits may be configured to operate a PMOS gate. The gate circuits may be configured to meet the reliability, breakdown, and power specifications of an ophthalmic device. The one or more gate circuits may comprise a first gate driver circuit. The first gate driver circuit may comprise a Resistive Level Shifter (RLS), as shown in FIG. 13. The first gate driver circuit may comprise a resistor and two HVNMOS switches. As an illustration, first gate driver circuit may be configured to operate as follows:
1. The Resistor (R1) holds the gate at Vhv such that the HVPMOS is biased off. Vhv is not conducted to the light-emitting device and no Idev flows.
2. The HVNMOS HVN1 switch gate is driven to the battery voltage (Vbatt, approximately 1.6 V). The HVN1 device conducts current Idrive which is supplied from Vhv through R1.
3. When the gate of HVN1 is driven to Vbatt, the gate of HVN2 is driven to ground. HVN2 is no longer conducting and releases the Vdev voltage.
4. The voltage at the gate of the HVPMOS device is lowered by Vhv−Idrive*R. This value is designed to turn the HVPMOS device on and allow conduction to the light-emitting device.
5. The gate of the HVNMOS device is taken to ground. Current no longer flows through R1 and the gate of the HVPMOS device is pulled up to Vhv. The HVPMOS device stops conduction.
6. The size of the HVNMOS device and resistor control the amount of current drawn from Vhv during operation. The size of the gate drive current may be limited to avoid causing Vhv to drop too rapidly.
7. The HVNMOS device can also be driven with current mirror and a switched reference source.
8. The sizes of resistor and HVPMOS and HVNMOS determine the maximum switching speed of the driver circuitry.

The first gate drive circuit described may be configured to operate an RSiD and/or an OLED based device.

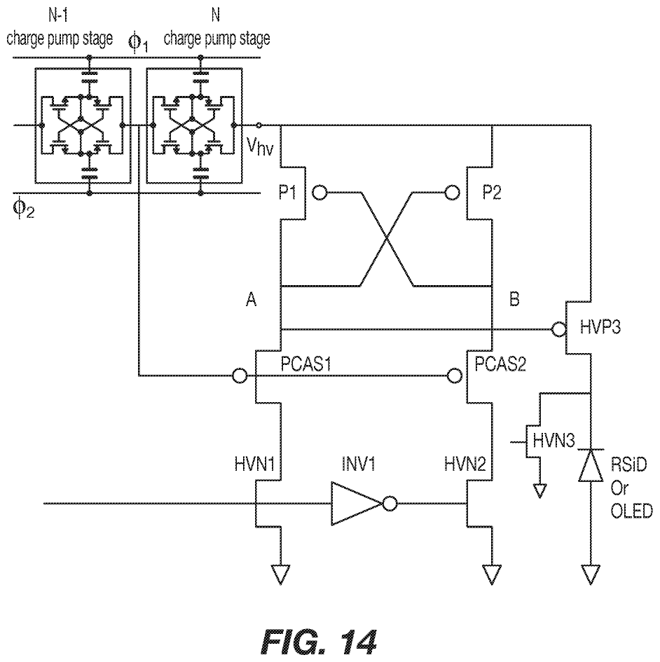

The ophthalmic device may comprise a second gate driving circuit. The second gate driver circuit may be used in addition to or instead of the first gate driving circuit. The second gate driving circuit may be used to drive the HVPMOS gate. The second gate driving circuit may comprise a Floating Level-Shifter (FLS), as shown in FIG. 14. As an illustration, the second gate driving circuit may be configured to operate as described below:
1. PCAS1 and PCAS2 are HVPMOS transistors used to protect the drains and gates of the cross-coupled LVPMOS transistors.
2. The gates of PCAS1 and PCAS2 are driven by the N−1 output of the charge pump voltage. This effectively clamps the voltage between Vhv and the drain of MPCAS1 and 2 to the battery voltage (Vbatt).
3. P1 and P2 are cross-coupled load transistors such that if the drain of P1 is pulled low P1 conducts and P2 is turned off. When the gate of P2 is pulled low P2 conducts and P1 is turned off.
4. HVNMOS transistors HVN1 and HVN2 are driven by logic signals of 0 volts to the battery voltage.
5. HVNN3 is a high-voltage NMOS transistor that resets Vdev to zero after light emission.
6. To turn on the light-emitting device, the gate of HVN1 is driven high and the gate of HVN2 is driven low through inverter INV1. Node A is pulled low turning on P2.
7. The gate of HVN3 is driven low, releasing Vdev.
8. HVN2 is off, P2 pulls node B to Vhv and turns off P1. The gate of the HVP3 is pulled low and Vdev is pulled high.
9. To turn off the light-emitting device, the gate of HVN1 is driven low and the gate of HVN2 is driven low. Node B is pulled low turning on P1.
10. HVN1 is off, P1 pulls node A to Vhv and turns off P2. The gate of HVP3 is pulled to Vhv.
11. The HVN3 gate is driven high and Vdev is pulled to ground.

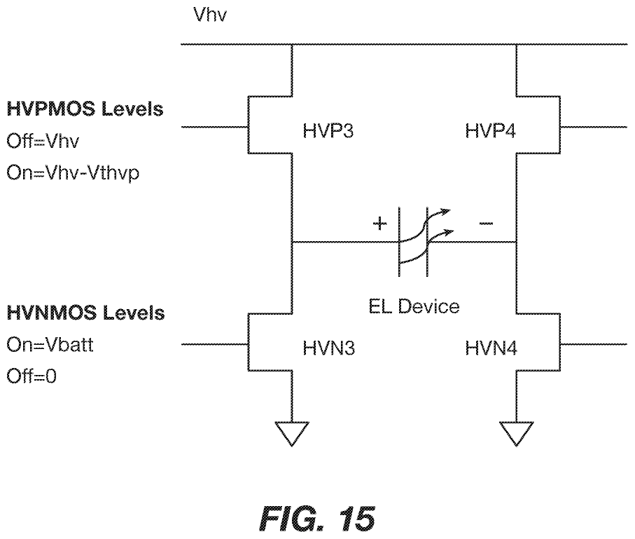

The ELD may be configured to use a high-voltage AC signal to emit light. To generate an AC signal, the charge pump may be used with an H-Bridge, as shown in FIG. 15. As an illustration, an example operation of the H-Bridge driver is described below:
1. Transistors HVP3 and HVP4 are high-voltage PMOS transistors. HVP3 and HVP4 are used to pull the terminals of the ELD to Vhv (high) in an alternating fashion.
2. The gates of HVP3 and HVP4 may be driven between Vhv and Vhv-Vthvp.
3. Transistors HVN3 and HVN4 are high-voltage NMOS transistors. They are used to pull the terminals of the ELD low in alternating fashion.
4. In the first cycle, HVP3 and HVN4 are turned on and the plus terminal of the ELD is pulled to Vhv and the negative terminal of the ELD is pulled low. HVP4 and HVN3 are turned off.
5. In the second cycle HVP4 and HVN3 are turned on pulling the negative terminal high and the plus terminal low. HVP3 and HVN4 are turned off.

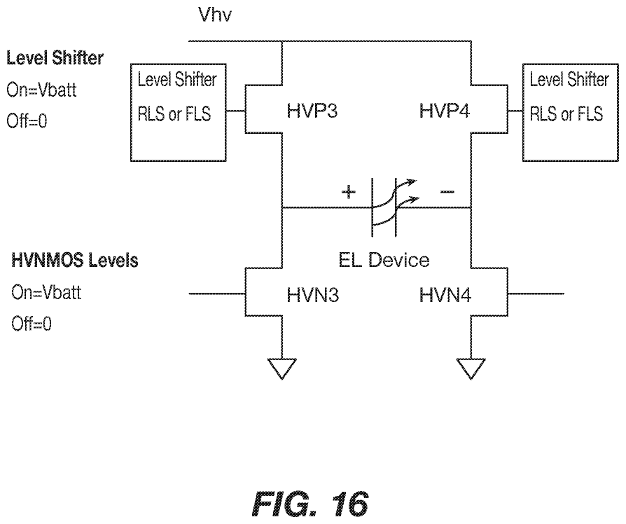

By alternating the cycles the ELD may driven with an alternating voltage sufficient to operate the ELD. The HVNMOS transistors can be driven with signals between 0 and Vbatt. The PMOS devices may be configured with level shifters to turn PMOS devices on and off. Either the Resistive Level Shifter (RSL) or the Floating Level Shifter can be used to drive HVP3 and HVP4 as shown in FIG. 16. In some implementations, the floating level shifter may be preferred as the floating level shifter does not draw static current.

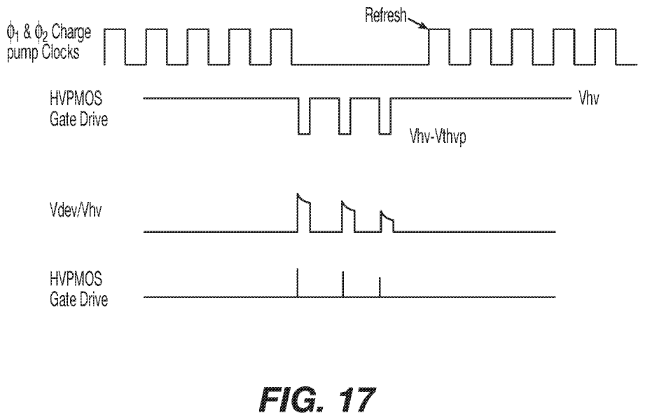

To operate within the battery capability, the average current drain during light emission operation may be limited to the nano-amp range. This limit may be accomplished by using narrow pulse widths to limit the current and sizing the reservoir capacitor to supply the peak currents sufficient for light emission. Example waveforms for operation of the RSiD are shown in FIG. 17. The signal names are referenced to FIG. 11.

The current through the light-emitting device may be controlled by using a controlled pulse width to turn on and off the HVPMOS transistor. When the HVPMOS transistor is turned on, Vdev is pulled up to Vhv. In the case of the RSiD, Vhv exceeds the breakdown voltage limit of the diode and current Idev flows from Vhv through the device to ground. Vhv is not being actively charge pumped at this time so the current is supplied by charge from the reservoir capacitor. Charge is removed from the capacitor which lowers the voltage of the capacitor. The charge and voltage are related by the expression Q=CV where Q is the charge on the capacitor, C is the capacitance value and V is the voltage on the capacitor. The voltage drop is governed by the equation dV=(I/C)*dT. dV is the change in voltage per unit time dT. I is the current flowing from the capacitor to ground and C is the capacitance value. dT is controlled by the pulse width of the HVPMOS gate drive. An example calculation shows how the average current can be limited to a nanoamp range while having mA peak currents. Assume the following initial values; C=50 pF, dT=200 nS, I dev=1 mA. Vhv=10V and Vdiode breakdown=6V. Vhv begins the cycle at 10V. The HVPMOS drive may be switched on for 50 nS. After the first HVPMOS gate pulse, the Vhv voltage change (dV) is 1 mA/50 pF*50 ns=1V. After the first pulse, Vhv moves from 10V to 9V. The current Idev drops a small amount each time Vhv is lowered depending on the device characteristic curve. The device reverse characteristic curve is relatively steep in breakdown and the current can be lowered significantly as the voltage approaches the breakdown voltage. A certain amount of current is required for the light emission. In order to meet this operation condition, the pulse width and starting Vhv is designed to maintain Vhv at least one volt higher than the breakdown voltage. For the example calculation, the second Idev current pulse is assumed to be 0.8 mA and the third Idev pulse 0.6 mA. After the second HVPMOS gate pulse, the Vhv voltage change (dV) is 0.8 mA/50 pF*50 ns=0.8V. Vhv moves from 9V to 8.2V after the second pulse. After the third HVPMOS gate pulse the Vhv voltage change (dV) is 0.6 mA/50 pF*50 ns=0.6V. Vhv moves from 8.2 V to 7.6V. If we assume that the off time of the charge pump is 2.5 μS. The total period is then 5 μS. The light-emitting device is on for 150 nS of this period. The average current is defined as the peak current times the duty cycle. The average for the peak current is 0.8 mA. The duty cycle is 150 nS/5 uS=0.030. The average current is 0.8 mA*0.030=24 μA for the period that the photonic communication system is transmitting. Additional current is required to operate the charge pump in the order of N*the average current, where N is the number of charge pump stages. For the RSiD with four charge pump stages the average current for the 0.030 duty cycle is 96 μA. The average current may be reduced by considering the duty cycle of the photonic communication to the overall operating time. If optical communication occurred 1% of the operating time in an 18-hour period, the average current is reduced to 96 nA. This allows the optical communication system to be employed 1% of the time drawing the equivalent of 96 nA from the battery. Total charge drawn would then be 6.2 m Coulombs. For a battery with a 90 μA-hr capability (324 m Coulombs) this would represent approximately 2% of the battery charge capacity. If photonic communications were increased above 1% more charge would be drawn from the battery. By limiting the switching time of the light-emitting device and limiting the amount of optical communication the photonic system can be designed to operate within the battery capacity. It is also possible to operate the driver circuit without stopping the charge pump. In this case the reservoir capacitor still acts to provide peak charges to the light-emitting device and smooth out the Vhv voltage drop. The net result for this operation is that the Vdev/Vhv will not drop as significantly as in the charge pump pause case. The current delivered to the light-emitting device will be more uniform. There is potential for some small additional losses in the charge pump switching onto the reservoir capacitor during this type of operation.

The ELD current consumption is different than the SLiD and the OLED. The ELD presents a capacitive load to the driving circuit such that only switching currents are generated. The current used to drive the ELD is governed Idev=CdV/dt. In this case the C is the capacitance of the ELD. Typical ELD exhibit a capacitance of 787 pF per meter of a 1 mm wide “tape”. The length of the ELD will be scaled to 1 mm to meet the volume requirements of the powered ophthalmic device. The resulting capacitance will be in the range of 800 fF. The change in voltage may be about 60V. The time to switch the voltage can be controlled. Assume a dT of 2 μS for the rise time of the switching waveform. Only switching the ELD terminals from ground to Vhv draws current from the battery. When the terminal is switched from Vhv to ground the current is delivered from the parasitic capacitance of the light-emitting device to ground and no additional charge is taken form the battery. Current is not drawn from the battery. The current drawn for each positive switching of the ELD driver terminals is: 800 fF*60/.5 uS=96 μA. This current is drawn each positive switching of the ELD terminal. This current is multiplied by 30 to account for the charge pump requirements. Consider the case where the ELD is driven at 240 kHz. The minimum number of 240 kHz pulses may be 2. This would yield a duty cycle of 0.48. The average current for ELD operation would be 1.34 CIA. If the optical communication occurred 1% of the time in an 18-hour operational period, the average current is reduced to 1.34 μA. This represents around 27% capacity of a 90 μA-hr battery.

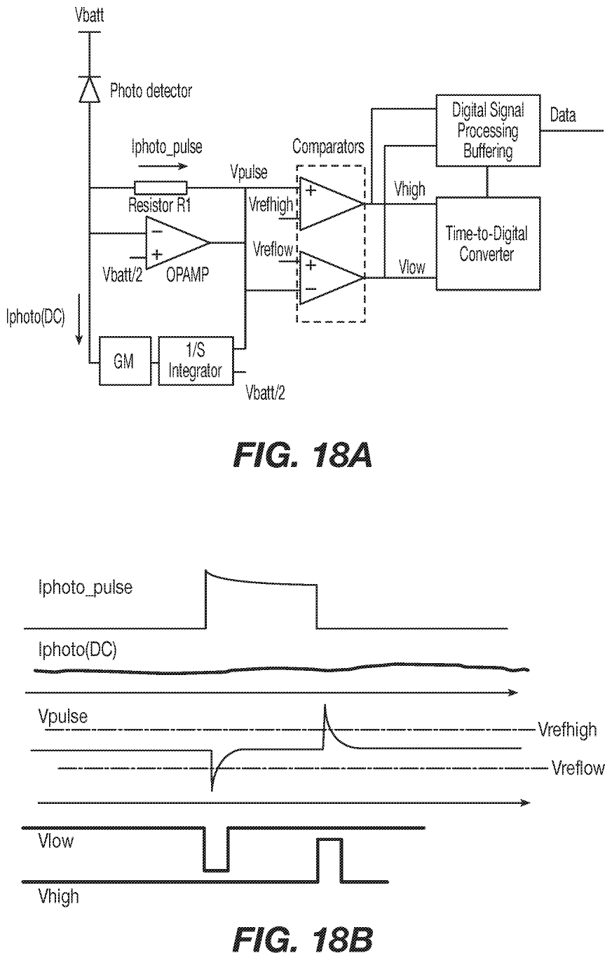

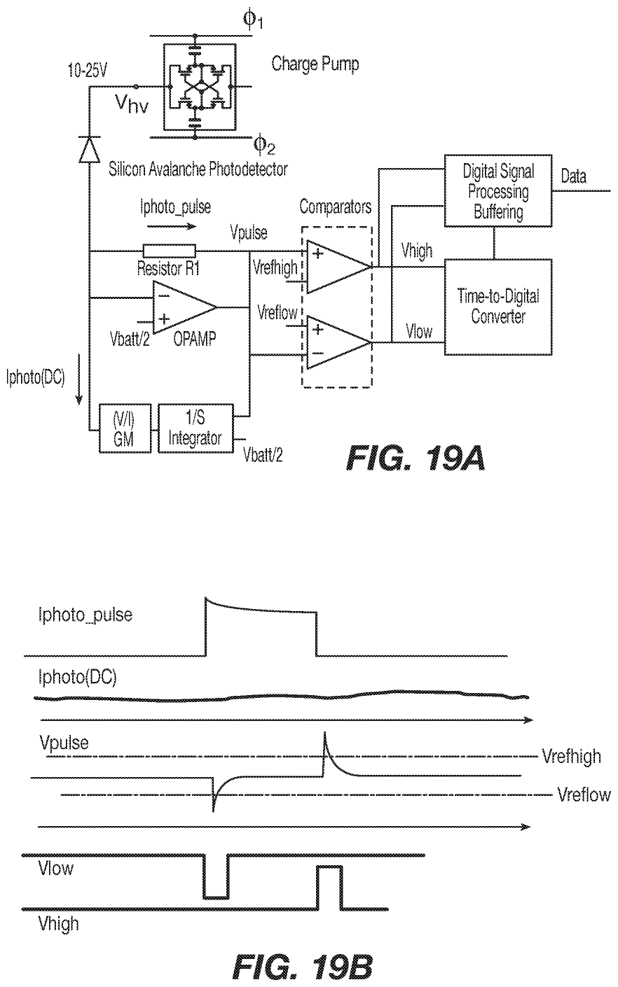

The light that will be emitted by the techniques described above may be configured to use specified pulse widths and optical power. Typical photonic receiver schemes can be used with the light-emitting techniques described. Additionally, the light-emitting techniques herein may be used with a novel, nonconventional photonic receiver as further described herein. To nullify the effects of the ambient light and dark current operating range and to increase pulse detection probability, a photonic receiver with specialized capabilities is disclosed below. The photonic receiver can be integrated into the same silicon IC used for the communication and driving circuitry of the photonic communication system. FIG. 18 shows a block diagram of the proposed photonic receiver. Operation and characteristics of the photonic receiver are described below. The photonic receiver may comprise a reverse-biased diode. Light is detected and transformed to a current (Idet) by the reverse-biased diode (photodetector). The photonic receiver may comprise a silicon avalanche photo-diode (SPAD). The advantage of the SPAD is that the SPAD has inherent gain due to the avalanche multiplication factor. The SPAD uses a reverse voltage and equivalent breakdown of approximately 25 V. The SPAD may be used with the charge pump and switching ciruitry described above for the light-emitting diode. Use of the SPAD increases the dynamic range and sensitivity of the receiver. This improvement increases the effective operating distance between transmitter and receiver. FIG. 19 shows an example photonic receiver using the SPAD.

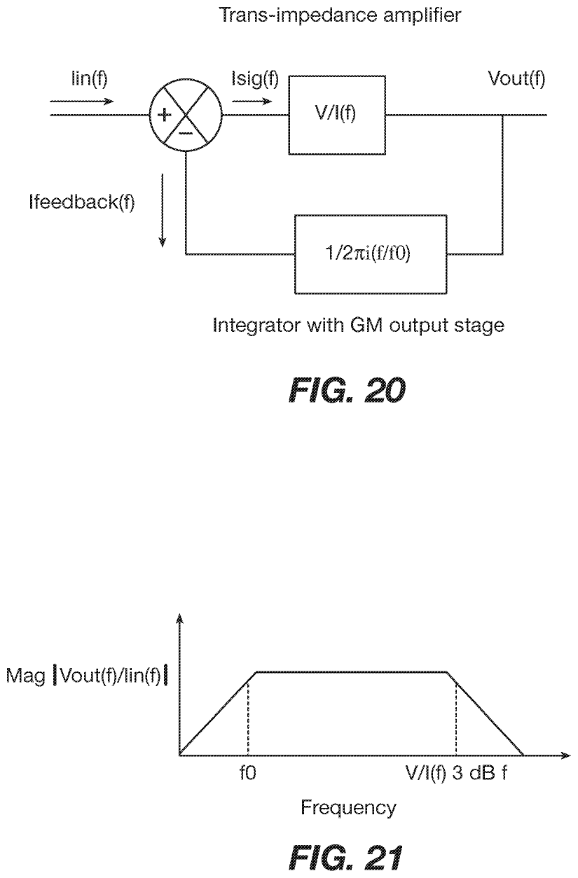

As a further explanation, the Idet current may be determined (e.g., sensed) by a trans-impedance amplifier, as shown in FIG. 20. A frequency dependent gain function is implemented by use of integrator feedback around the trans-impedance amplifier. The frequency dependent function has a high-pass characteristic which may be determined by the value of the frequency pole of the integrator (f0). The high-frequency cutoff may be determined by the frequency dependence of the trans-impedance amplifier (V/I(f)). FIG. 21 shows a block diagram and associated transfer functions of the integrator feedback circuitry. The input into the trans-impedance amplifier is a current signal. The integrator may comprise a voltage-mode circuit. To null DC and slow time-varying currents, the voltage-mode output of the integrator may be converted to a current. A trans-conductance (GM) stage is inserted between the integrator output and the current input to convert the integrator output into a feedback current. The GM stage may act as a voltage-to-current converter. The range and resolution of the currents are determined by the input voltage range and the value GM implemented in the trans-conductance stage. The GM stage may generate a current which sinks or sources any current input that is below the high pass frequency pole of the integrator feedback amplifier. If a DC or slow time-varying input current is input to the trans-impedance amplifier, the voltage output of the trans-impedance amplifier changes which in turn changes the integrator voltage input. The integrator voltage output changes per the transfer function. The output voltage of the integrator is input to the GM stage. The GM stage converts the voltage to a current which nulls the input current to the trans-impedance amplifier. In this manner, any signals with frequencies lower than the integrator pole are nulled. The circuitry used for these functions can be continuous time or sampled data. By using this configuration, DC currents including dark currents, from the detector, and ambient light currents are nulled. Only a current pulse or time-varying signal above the high pass cut-off frequency will be processed by the trans-impedance amplifier. The trans-impedance amplifier converts an input current into a voltage. The trans-impedance amplifier can be a continuous time circuit or a sampled data circuit. The sampled data circuit has some advantage that additional offset and operating range techniques can be applied. The size of the trans-impedance gain is determined by the size of the feedback resistor (R1). In a sampled data circuit, a large-valued resistor can be built by using an optimized clock frequency (f) with a set of switches and a small valued capacitor (C). The effective resistance is 1/fC. The time-varying Idet signal shows up as an inverted voltage pulse (Vpulse) on the output of the trans-impedance amplifier. Two comparators with a settable reference voltage range (Vrefhigh, Vreflow) may be used to process the voltage pulse. When the pulse exceeds the reference voltage the output of the Vrefhigh comparator changes state. The change in state of the comparator voltage is then encoded as a digital 1 or zero, and this signal may be used as data for the digital communication system. When the pulse is lower than Vreflow, the Vreflow comparator changes state. The change in state of the two comparators is used to encode digital 1s or 0s. Additional reliability can be added by checking the pulse width of the received signal. The falling edge of the Vreflow comparator pulse can be used to start a time-to-digital converter. The rising edge of the Vrefhigh comparator pulse can be used to stop the time-to-digital converter. The measured time between the stop and start is input to the digital signal processing block and then compared to a template of valid pulse widths and determination of pulse validity be made. The data is held in a buffer while pulse validity is checked. If the pulse is valid a digital pulse of the correct width is output from the buffer on the data line. If the pulse is not valid the buffer is cleared and the measurement sequence reset. Effectively, the receiver may only detects time-varying signals. The characteristics of the time-varying signals can be analyzed to see if the characteristics meet the criteria produced by the coupled light-emitting device. Ambient lighting and dark current from the detector, stray light pulses and light switched at an incorrect frequency are all rejected by this receiver.

The receiver may be uniquely suited to process light pulses. In the case of blink/eyelid detection, the photodetector is located within the ophthalmic device on the eye looking outward. During a blink, the eyelid is closed preventing light from entering the eye. The photodetector sees a change in light level in the form of a falling pulse that begins as the eyelid closes. The light level detected remains “low” while the eyelid is closed and then returns to its original state when the eyelid is opening. The time between the falling pulse can be determined using the receiver and pulse width measured using a time-to-digital converter. The pulse width can be compared to a template to ensure that the light pulse meets a valid blink criteria. During the time surrounding the blink the ambient light level changes at a slow time-varying rate. This change in ambient light is rejected by the receiver. Sudden flashes or changes in ambient light can be ignored if they do not meet the blink timing criteria. The receiver time constants are tuned to accommodate the blink waveform. By using this receiver in this manner a very high probability of accurate blink detection can be guaranteed with minimal circuitry.

The transfer function is: Vout/Iin(f)=V/I(f)/1+V/I(f)*I/V(f*f0) where:
f is the frequency of the signal
(f) indicates a function of f
f0 is the integrator pole frequency
i is the imaginary operator

Rearrangement of the terms yields:

Vout/Iin(s)=[2πi(f/f0)*(V/I(f)]/[1+2πi(f/f0)]

A plot of this transfer function magnitude vs. frequency is shown in FIG. 21.

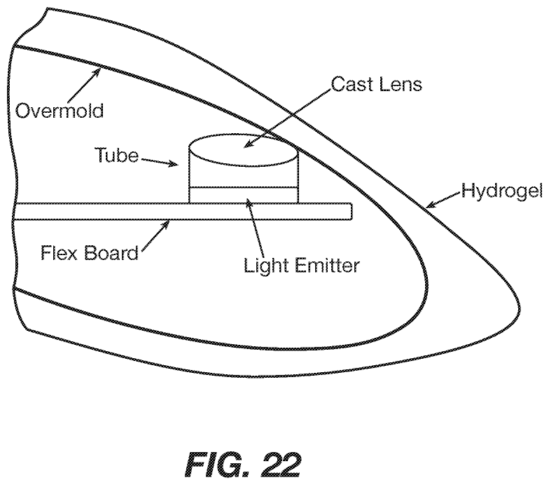

The light-emitting sources are incoherent light at varying frequencies. To improve the transmission and detection of this light optical methods can be employed in the powered ophthalmic device to enhance the characteristics of the emitted light. The light-emitting devices may reside in the powered ophthalmic device in an area outside the pupil of the eye. The light-emitting device may be embedded in an overmold material inside a hydrogel lens. In this case, the overmold material could be cast such that an optical lens could be built in the overmold above the light-emitting device. This lens would act to focus and collimate the output of the light-emitting device. In addition, a tube could be built into the overmold to direct the light from the device to the lens. The focus of this light would increase the effective working distance of the light-emitting device. FIG. 22 shows an example ophthalmic device comprising a photonic transmitter and/or photonic receiver.

On the receiver side, a lens could be implemented that focuses the light onto the photodetector. Use of this lens would increase the intensity of light available at the receiver input. The details of the receiver lens will be determined by the location and implementation of the photonic receiver.

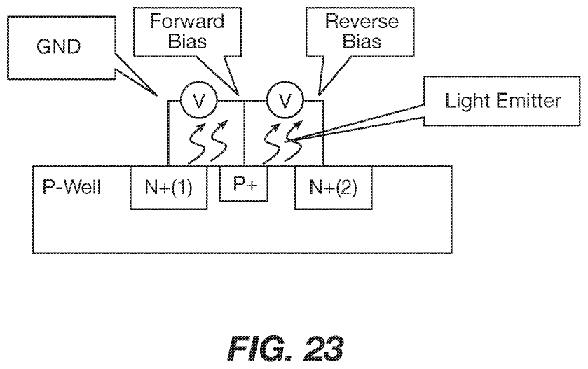

In an aspect, another alternative device is proposed to implement the photonic transmitter. The photonic transmitter may comprise a light-emitting transistor, such as silicon light-emitting transistor. The light-emitting transistor may comprise a three terminal Silicon Light-Emitting Transistor (SLET). The light-emitting transistor may be integrated within a standard CMOS processes. The light-emitting transistor may comprise the same benefits of the RSiD and has the additional feature that the light can be switched on and off using a low voltage switching signal and does not require high-voltage switching techniques. An example SLET is illustrated in FIG. 23.

As an illustration, an example operation of the SLET is described below:
1. A bias voltage (e.g., the first voltage) of 6-9 volts is applied to the N+(2) terminal. This effectively reverse biases that junction.
2. A forward bias of 1-2 V (e.g., the third voltage) is applied between the N+(1) terminal and the P+ terminal.
3. The reverse bias between N+(2) and P+ creates a large electric field. Minority carriers (holes) that reach the edge of this electric field are accelerated and avalanche. Avalanche is phenomena in which hot carriers collide with the lattice creating additional “hot” carriers. In this case 1 carrier becomes 2 and 2 become 4 and so on until there is an “avalanche” of carriers.
4. Because of the doping of the N+ region there are a small number of minority carriers available to avalanche the light producing efficiency is low.
5. The forward biased P+ and N+(1) junction provide the minority carriers that can contribute to the avalanche photon production.
6. As the carriers travel in the material and collide with the lattice they eventually relax from their excited state due to collision “braking” force. Photons are emitted during this relaxation process.
7. If the forward bias is not applied the optical generation is quenched.
8. If the reverse bias is lowered significantly the optical generation is quenched.
9. Operation of the device can be implemented by leaving the reverse bias on N+(2) and switching the forward bias between P+ and N+(1) between zero and 1-2 V.

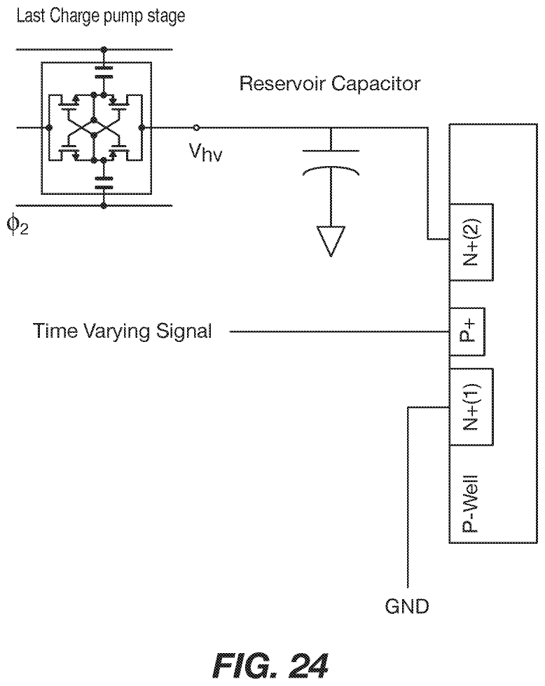

In an aspect, a novel driving circuit and/or switching technique may be used to operate the SLET. As with the other circuits a voltage higher than the supply (6-9V) is required for operation. This higher voltage can be generated with similar techniques as described above, and in this case the charge pump circuit is one circuit that could be used for this operation. The difference of the SLET compared to the other circuits is that no high-voltage switching or high-voltage level shifting is required. An example SLET with a driving circuit for the SLET is illustrated in FIG. 24.

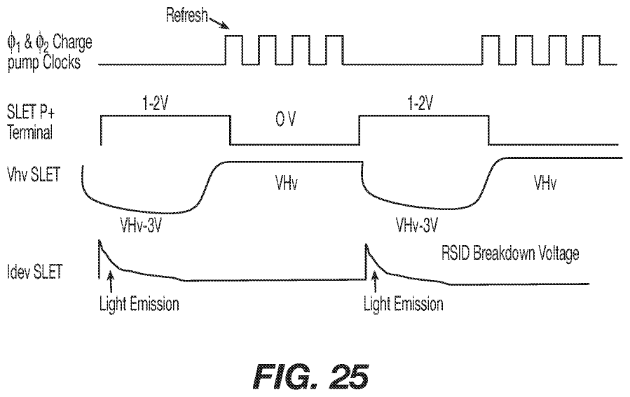

FIG. 25 is a diagram illustrating an example operation of the SLET and driving circuit. As an illustration, an example operation of the SLET driving circuit is described below:
1. The charge pump is operated and Vhv is pumped up to 6-9 V.
2. The charge pump can continue to run or be cycled off to conserve charge.
3. The reservoir capacitor is charged to Vhv.
4. A time-varying signal of 1-2V is applied to the P+ terminal of the SLET.
5. When the P+ terminal is at 1-2V the SLET conducts current from the reservoir capacitor (and charge pump if operating) and light is emitted from the device.
6. When the P+ terminal is tied to gnd or zero volts relative to the N+(1) junction no light is emitted and only leakage currents flow.
7. The charge pump can be cycled to pump the reservoir capacitor back up to Vhv.
8. The signal operation can be timed with the charge pump for optimal charge consumption.

An example SLET that may be used as a light-emitting device in an ophthalmic device herein is described in more detail in the following paper: “Two order increase in the quantum efficiency of silicon CMOS n+pn avalanche-based light-emitting devices as a function of current density” Synman et al. IEEE Electron Device Letters, vol. 20, no. 12, pp. 614-617, published December 1999, the entirety of which is herein incorporated by reference.

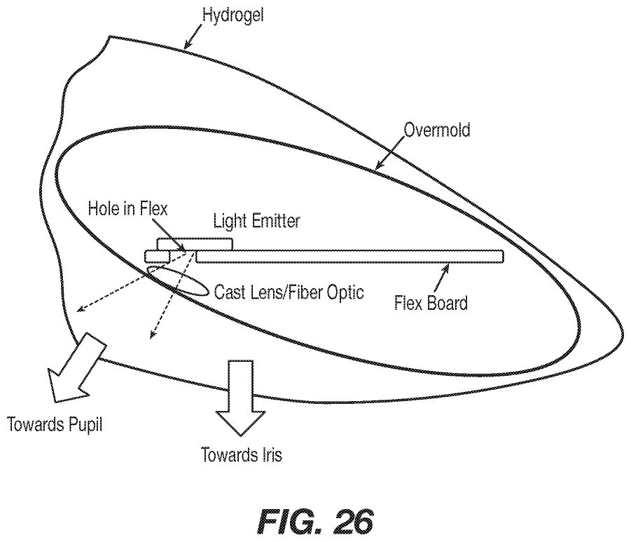

In an aspect, the light-emitting devices described herein may also be used to emit light as part of an alert system. In this approach, a light-emitting device may be mounted in an ophthalmic lens such that the light-emitting portion faced an iris of the wearer. In this system, other sensors such as the eyelid position sensor or the pupil diameter sensor could send a signal to flash the light-emitting device such that the user would see the light and be altered. For example, studies have been conducted that eyelids close for longer and longer periods as a person becomes drowsy. A special case of this would be when someone was driving. A lid position sensor could signal a threshold of lid closure and then send an alert signal to the controller which in turn flashes the light-emitting device. In order for the light-emitting device to work as an alert device, the light-emitting device may be configured to transmit light to the retina through the pupil. The light-emitting device may be positioned to ensure proper illumination of the retina. Example, positioning of the light-emitting device is illustrated in FIG. 26. In an aspect, the light-emitting device may be positioned proximate an edge of the pupil (e.g., as close to the edge of the pupil as possible). The light-emitting device may be tilted to the corresponding proper geometry of the eye. In another aspect, light-emitting device may be coupled (e.g., optically coupled, mechanically coupled) to an optical guide, such as a fiber optic or lens within the overmold of the powered ophthalmic lens. For example, the optical guide may be configured to direct light from the light-emitting device to the pupil.

In an aspect, the methods and systems described herein may comprise a photonic communications system. The photonic communications system may comprise a light transmitter and/or a light receiver. The photonic communications system may comprise a supporting timer, driver, amplification and signal processing circuitry that can operate within the battery capacity and volume requirements of a powered ophthalmic device.

The methods and systems described herein may comprise a method of modulating and demodulating the light transmission and reception for digital communications.

The methods and systems described herein may comprise a reverse silicon breakdown diode with driving circuitry and method that emits light pulses. The light emitter can be implemented in standard HV CMOS process and meets the volume and battery capacity requirements of the powered ophthalmic device.

The methods and systems described herein may comprise an OLED with driving circuitry and method that emits light pulses. The light emitter is compatible with standard HVCMOS with the addition of specialized organic layer deposition. The light emitter meets the volume and battery capacity requirements of the powered ophthalmic device.

The methods and systems described herein may comprise an Electro-Luminescent device with driving circuitry and method that emits light pulses. The light emitter is compatible with standard HVCMOS processes and meets the volume and battery capacity requirements of a powered ophthalmic device.

The methods and systems described herein may comprise a silicon Avalanche photo diode and driving circuitry that detects light pulses and can be implemented in standard HVCMOS process. The detector meets the volume and battery capacity requirements of the powered ophthalmic device.

The methods and systems described herein may comprise a photonic receiver that amplifies light pulses within a specified bandwidth and rejects ambient light, dark current and other low frequency time-varying signals.

The methods and systems described herein may comprise a photonic receiver with the addition of a comparator and time-to-digital converter and digital signal processing functions to perform pulse width analysis to determine if the detected pulse is a valid signal. The photonic receiver may be configured to the volume and battery capacity requirements of the powered ophthalmic device and can be implemented in standard CMOS or HVCMOS technology. The photonic receiver may be implemented in a powered ophthalmic lens, using a time-to-digital converter and tuned time constants to accurately detect eye blinks in changing ambient conditions.

The methods and systems described herein may comprise a lens built into the overmold of a powered ophthalmic device that focuses and collimates the light from the light emitter and increases the effective working distance of the communication link. The lens may or may not interface to an optical tube.

The methods and systems described herein may comprise a lens built into the photonic receiver which focuses light onto the photo-detector increasing the received intensity of light.

The methods and systems described herein may comprise a lens built into the photonic receiver which is frequency selective and tuned to the bandwidth of light produced by a specific light emitter.

In an aspect, the methods and systems described herein may comprise an ophthalmic device. The ophthalmic device may comprise an ophthalmic lens configured to be disposed on or in an eye of a user. The ophthalmic lens may comprise a contact lens or an implantable lens, or a combination of both. The contact lens may comprise a soft contact lens. The contact lens may comprise a hybrid contact lens having a hard component and a soft component. The soft component may comprise a soft lens. The hard component may comprise an electrical component, mechanical component, circuitry, and/or the like. The ophthalmic lens may have an optic zone and a peripheral zone. The ophthalmic device may comprise a variable optic element incorporated into the optic zone of the ophthalmic lens. The variable optic element may be configured to change a refractive power of the ophthalmic lens.

The ophthalmic device may comprise a sensor disposed in the peripheral zone of the ophthalmic lens. The sensor may be configured to detect a characteristic of a user of the ophthalmic device. The sensor may be further configured to provide a sensor output. The sensor may comprise one or more contacts configured to make direct contact with a tear film of the eye. The sensor may comprise a displacement sensor, a temperature sensor, an impedance sensor, or a capacitance sensor. The characteristic may comprise impedance associated with a movement of a ciliary muscle of the user. The characteristic may comprise vibration associated with a movement of a ciliary muscle of the user. The characteristic may comprise capacitance associated with a position or movement of one or more of an upper eyelid and a lower eyelid of the user. The characteristic may comprise temperature on or adjacent the eye of the user.

The ophthalmic device may comprise a processor. The processor may be disposed in the peripheral zone of the ophthalmic lens. The processor may be configured to determine communication data. The communication data may be determined based on the sensor output. For example, the processor may be configured to analyze the sensor output. The sensor output may be compared to one or more thresholds. The sensor output may be analyzed to determine a pattern or signature of user behavior and/or characteristics. The sensor output may be analyzed to determine to send a notification to a remote device (e.g., mobile device, another ophthalmic device, a fob, a tablet, a laptop, a computer, a base station). The sensor output may be analyzed to determine a condition has be satisfied. For example, the sensor output may be compared, matched, and/or otherwise processed to data stored by the ophthalmic device representing one or more transmission actions. The transmission actions may be associated with corresponding communication data. For example, the sensor output may be analyzed to determine a health characteristic, such as a hydration level. If the hydration level determined to be below a threshold, the processor may determine communication data associated with indicating that the user's hydration level is below the threshold.

The communication data may be determined based on other conditions, such as a schedule (e.g., regular times for uploading sensor data), moving within range of (e.g., or otherwise being positioned for communication) a receiver (e.g., such as a base station), upon initiation by a user (e.g., by a gesture, pressing a button, etc.). The conditions may be associated with transmission of various types of data, such as stored data, system parameters (e.g., battery level, memory, error messages), sensor data, device usage, and/or the like.

In some scenarios, the communication data may be unrelated to characteristics of the user. For example operational data and status (e.g., power on, power off) may be transmitted externally.

The ophthalmic device may comprise a power source configured to supply power to at least one of the ophthalmic lens, the sensor, and the processor. The power source may comprise a battery, a capacitor, an energy harvester, a combination thereof, and/or the like. The power source may comprise an external power source stored on the user (e.g., external to the ophthalmic lens) or stored external to the user. The power source may be configured to charge wirelessly.

The ophthalmic device may comprise a light-emitting device. The light-emitting device may be configured to transmit a light signal outwardly from the ophthalmic device. The light signal may represent the communication data. The light-emitting device may comprise a photonic transmitter. The photonic transmitter may be configured to generate the light signal.

The light-emitting device may comprise (e.g., or be electrically coupled to) a driving circuit electrically coupled to the photonic transmitter. The driving circuit may be configured to cause the photonic transmitter to generate the light signal based on the communication data. The driving circuit may be configured to generate a first voltage larger than a second voltage of the power source. The driving circuit may be configured to switch a connection between the photonic transmitter and the first voltage on and off to generate the light signal.

The driving circuit may comprise a charge pump configured to multiply the second voltage of the power source to generate the first voltage. The driving circuit may comprise a storage capacitor electrically coupled to an output of the charge pump and configured to store the first voltage. The charge pump may comprise a plurality of stages. A number of the plurality of stages may be based on a voltage for operating the photonic transmitter.

The driving circuit may be configured to perform modulation to generate the light signal. The driving circuit may generate the light signal as a sequence of light pulses. The modulation may comprise amplitude modulation. The driving circuit may be configured to perform on-off key switching to cause the photonic transmitter to transmit pulse signals based on the communication data.

In an aspect, the photonic transmitter may comprise one or more of a reverse-biased silicon diode (RSiD), an organic LED (OLED), a combination thereof, and/or the like. The driving circuit (e.g., for the RSiD and/or OLED) may comprise a transistor, such as a p-channel (e.g., or n-channel in some implementations) metal-oxide semiconductor (PMOS) transistor. The PMOS transistor may be a high-voltage PMOS transistor (HVPMOS). The PMOS transistor may be configured to supply the first voltage to the photonic transmitter when a threshold gate voltage is supplied to a gate of the PMOS transistor. Threshold gate voltage may be lower than the first voltage. The driving circuit may comprise a resistive level shifter configured to control the gate of the PMOS transistor. The driving circuit may comprise a floating level shifter configured to control the gate of the PMOS transistor.

In an aspect, the photonic transmitter may comprise an electro-luminescent device (ELD). The driving circuit (e.g., for the ELD) may comprise an H-bridge. The H-bridge may comprise two transistors, such as p-channel (e.g., or n-channel) metal-oxide semiconductor (PMOS) transistors. The two transistors may be high-voltage PMOS transistors (HVPMOS). The two transistors may be configured to alternate between supplying the first voltage to a positive terminal of the photonic transmitter and supplying the first voltage to a negative terminal of the photonic transmitter. The driving circuit may comprise a resistive level shifter configured to control gates of the two transistors. The driving circuit may comprise a floating level shifter configured to control gates of the two transistors.

In an aspect, the photonic transmitter may comprise a photonic transmitter comprising a light-emitting transistor. The driving circuit may be configured to cause a current based on the first voltage to switch on and off for the photonic transmitter to generate the light signal. The light-emitting transistor comprises a silicon light-\emitting transistor. The light-emitting transistor may be configured to emit light based on an avalanche effect of charge carriers. The driving circuit may be configured to cause the avalanche effect. The driving circuit may be configured to apply a reverse bias to one or more terminals of the light-emitting transmitter thereby causing the avalanche effect of charge carriers. The light-emitting transistor may comprise a first n-doped region, a second n-doped region, and a p-doped region. The driving circuit may be configured to supply the first voltage to a first n-doped region, and a time-varying signal to one or more of the p-doped region and the second n-doped region. The time-varying signal may comprise a signal that switches between a third voltage and a fourth voltage. The third voltage may be zero (e.g., substantially zero). The fourth voltage may comprise a low voltage, such as a voltage lower than the first voltage. The fourth voltage may comprise any voltage from about 1 V to about 2 V.

The ophthalmic device may further comprise an optical layer. The optical layer may be disposed outward from the light-emitting device. For example, the optical layer may be disposed on a side of the ophthalmic device configured to be disposed away from the eye of the user. The optical layer may be configured to collimate and/or focus the light signal (e.g., from the photonic transmitter). The optical layer may comprise a tube configured to direct the light signal in a particular direction (e.g., away from the ophthalmic device). The optical layer may comprise a secondary lens to focus the light signal.

In an aspect, the ophthalmic device may comprise a light detection device (e.g., a receiver). The light detection device may be configured to generate a data signal based on light received at the ophthalmic device. In some implementations, the ophthalmic device may comprise the light detection device without the light-emitting device. In some implementations, the ophthalmic device may comprise the light-emitting device without the light detection device. In some implementations, the ophthalmic device may comprise the light-emitting device and the light detection device.

The light detection device may comprise a photonic detector configured to convert light pulses into an electrical signal. The photonic detector may comprise a light-emitting diode. For example, the photonic detector may comprise a reverse-biased diode. The photonic detector may comprise a silicon avalanche photo diode.

The light detection device may comprise a filter electrically coupled to the photonic detector and configured to output filtered signals within a predetermined frequency range based on the electrical signals. The filter may comprise a hardware filter, such as a circuit configured to filter out signals outside of the frequency range. The filter may be configured to filter out ambient light changes. The filter may comprise a trans-impedance amplifier configured to amplify the filtered signals within the predetermined frequency range.

The light detection device may comprise a converter. The converter may be electrically coupled to the filter. The converter may be configured to output the data signal based on the filtered signals. The data signal comprises a digital signal of variable pulse width based on time-varying characteristics of the filtered signals. The converter may comprise a first comparator configured to output a first signal in response to receiving a voltage above a first reference voltage. The converter may comprise a second comparator configured to output a second signal in response to receiving a voltage below a second reference voltage. The converter may comprise a time-to-digital converter configured output the digital signal based on the first signal and the second signal.

The light detection device may be in communication with (e.g., electrically coupled to) a processor. The processor may comprise the processor of the ophthalmic device (e.g., described above) or a separate processor (e.g., dedicated to the light detection device). The processor may be configured to determine communication data based on the data signal.

An optical layer, such as the optical layer described above or a separate optical layer, may be configured to enhance light signals received by the ophthalmic device. The optical layer may be configured to focus light on at least a portion of the light detection device. The optical layer may be configured to filter out light outside of a frequency range. The frequency range may be associated with a signal transmitter configured to transmit photonic signals to the ophthalmic device.

The light detection device may be fabricated using a complimentary metal-oxide semiconductor (CMOS) process. The light detection device may be disposed on a silicon based integrated circuit. In an aspect, the light detection device may be on the same chip, wafer, and/or integrated circuit as the light-emitting device. At least a portion of the light detection device may be on the same chip, wafer, and/or integrated circuit as at least a portion of the light-emitting device. In another aspect, the light detection device and the light-emitting device may be disposed on different chips, wafers, and/or integrated circuits.

The light detection device may be configured to detect signals transmitted from remote devices and/or signals generated by a user. For example, a user may generate a signal by blinking (e.g., or otherwise moving one or more eyelids in a pattern). The processor may be configured to detect an eye blink by comparing a pulse width of a digital signal to a template (e.g., associated with eye blinking).

The processor may be configured to modify a parameter based on the communication data. The parameter may be associated with the sensor. For example, the parameter may comprise a calibration setting, such as an accommodation threshold. The parameter may comprise an operational mode, such as high performance, default operation mode, power saving mode, a calibration mode, customization mode, and/or the like. The communication data may comprise a configuration profile associated with the user. The configuration profile may comprise operational settings associated with (e.g., defined by) the user. The configuration profile may comprise an accommodation threshold (e.g., associated with activating the lens to assist a user in accommodation), a hysteresis setting (e.g., associated with preventing cycling on and off the lens), a calibration setting, a vergence setting (e.g., indicative of a distance between the user's eyes), and/or the like.

The processor may be configured to communicate with the user based on the communication data. For example, the processor may determine to alert the user based on the communication data. The alert may comprise a health warning (e.g., dehydration, low pulse, vision problem), a notification that the user received a call or message at a remote device, and/or the like.

In an aspect, a light-emitting device may be configured to transmit a light signal from the ophthalmic device to the eye of the user. The light signal may represent communication data determined by the processor. The light-emitting device may comprise a photonic transmitter as described herein. For example, the photonic transmitter may comprise one or more of a reverse-biased silicon diode (RSiD), an organic LED (OLED), a silicon light-emitting transistor, or an electro-luminescent (EL) device. The light-emitting device may comprise a driving circuit corresponding to the photonic transmitter. The ophthalmic device may have multiple light-emitting devices, such as a light-emitting device configured to transmit light to the eye of the use and a light-emitting device configured to transmit light outward from the eye of the user.

The light-emitting device may be configured to transmit the light signal to the eye via an optical guide. The optical guide may comprise a fiber optic or lens. The optical guide may be disposed the ophthalmic lens. For example, the optical guide may be disposed within the overmold of the ophthalmic lens. The light-emitting device may be positioned to transmit the light signal to pupil of the eye. For example, the light-emitting device may be angled towards the pupil of the eye. The light-emitting device may be adjacent, proximate to, and/or within a threshold distance of the iris of the eye.

The processor may be configured to determine communication data associated with communicating with the user based on communication data received from an external source. The external source may comprise one or more of a smart device, a watch, a mobile phone, or a wireless transmitter. The communication data received from the external source may comprise one or more of an alert, a notification, or a message. For example, if a mobile phone is ringing, and/or receives a notification or text message, a corresponding light signal may be flashed to the user indicative of the type of notification, source of the notification, priority of the notification, and/or the like.

The ophthalmic device may be configured to transmit light to the eye if an alert mode is enabled. For example, a user may set a parameter to receive alerts associated with a mobile device or other smart accessory (e.g., smart watch, smart apparel). If the alert mode is enabled, the notifications may be sent to the ophthalmic device which may store a variety of different light signals to convey different information to the user. For example, different lengths of light pulses, different colors, and/or brightness levels may be associated with different types of information, such as urgent information, priority email message, or notification of low battery level. The alerts may also relate to health characteristics of the user. For example, a light signal may be transmitted to the user if an irregular heart rate is detected or a heartbeat above or below a threshold is detected (e.g., detected by either the ophthalmic device or another device, such as a smart watch or activity tracker). In an aspect, the alert may comprise a wakeup signal. For example, the ophthalmic device may detect that a user is driving (e.g., based on GPS and/or accelerometer data). The ophthalmic device may also detect that a user's eyelids are beginning to close (e.g., or become droopy, indicating sleepiness). The movement of the eye lids may match a pattern of movement indicative of sleepiness. The ophthalmic device may send a series of light signals (e.g., flashes) to awaken the user. Other alarm conditions may be detected, such as environmental conditions (e.g., toxic gases), user set conditions (e.g., wake-up alarm), temperature alarms, body saturation (e.g., water saturation levels) alarms, glucose alarms, and/or the like. Similarly, a light-emitting device configured to emit light outward from the user may also send alarms to alert rescue professions, caregivers, and/or the like.

In an aspect, the processor may be configured to determine communication data associated with communicating with the user based on sensor data of a sensor of the ophthalmic device. The sensor may comprise one or more contacts configured to make direct contact with a tear film of the eye. The sensor is a displacement sensor, a temperature sensor, an impedance sensor, or a capacitance sensor. The processor may be configured to determine a characteristic of the user based on the sensor data and determine communication data based on the characteristic. The characteristic may comprise impedance associated with a movement of a ciliary muscle of the user.

The characteristic may comprise vibration associated with a movement of a ciliary muscle of the user. The characteristic may comprise capacitance associated with a position or movement of one or more of an upper eyelid and a lower eyelid of the user. The characteristic comprises temperature on or adjacent the eye of the user.

Although shown and described in what is believed to be the most practical and preferred embodiments, it is apparent that departures from specific designs and methods described and shown will suggest themselves to those skilled in the art and may be used without departing from the spirit and scope of the disclosure. The present disclosure is not restricted to the particular constructions described and illustrated, but should be constructed to cohere with all modifications that may fall within the scope of the appended claims.

What is claimed is:

1. An ophthalmic device comprising:
an ophthalmic lens configured to be disposed on or in an eye of a user;
a processor disposed in the ophthalmic lens, the processor configured to determine communication data;
a power source configured to supply power to at least one of the ophthalmic lens, the sensor, and the processor; and
a light-emitting device configured to transmit a light signal outwardly from the ophthalmic device, the light signal representing the communication data, wherein the light-emitting device comprises:
a photonic transmitter comprising one or more of a reverse-biased silicon diode (RSiD) or an organic LED (OLED); and
a driving circuit configured to cause the photonic transmitter to generate the light signal based on the communication data, wherein the driving circuit is configured to generate a first voltage larger than a second voltage of the power source and switch a connection between the photonic transmitter and the first voltage on and off to generate the light signal.

2. The ophthalmic device of claim 1, wherein the driving circuit comprises a high-voltage p-channel metal-oxide semiconductor (HVPMOS) transistor configured to supply the first voltage to the photonic transmitter when a threshold gate voltage is supplied to a gate of the HVPMOS transistor, wherein the threshold gate voltage is lower than the first voltage.

3. The ophthalmic device of claim 2, wherein the driving circuit comprises a resistive level shifter configured to control the gate of the HVPMOS transistor.

4. The ophthalmic device of claim 2, wherein the driving circuit comprises a floating level shifter configured to control the gate of the HVPMOS transistor.

5. The ophthalmic device of claim 1, wherein the driving circuit comprises a charge pump configured to multiply the second voltage of the power source to generate the first voltage.

6. The ophthalmic device of claim 5, wherein the driving circuit comprises a storage capacitor electrically coupled to an output of the charge pump and configured to store the first voltage.

7. The ophthalmic device of claim 1, wherein the driving circuit is configured to perform on-off key switching to cause the photonic transmitter to transmit pulse signals based on the communication data.

8. The ophthalmic device of claim 1, further comprising an optical layer disposed outward from the light-emitting device and configured to one or more of collimate and focus the light signal.

9. The ophthalmic device of claim 1, wherein the power source comprises a battery.

10. The ophthalmic device of claim 1, wherein the ophthalmic lens comprises a contact lens.

11. The ophthalmic device of claim 10, wherein the contact lens comprises one or more of a soft contact lens or a hybrid contact lens having a hard component and a soft component.

12. The ophthalmic device of claim 1, further comprising
a variable optic element incorporated into the ophthalmic lens, the variable optic element being configured to change a refractive power of the ophthalmic lens;
a sensor disposed in the ophthalmic lens, the sensor configured to detect a characteristic of a user of the ophthalmic device, the sensor further configured to provide a sensor output, wherein the communication data is based on the sensor output.

13. The ophthalmic device of claim 12, wherein the sensor is a displacement sensor, a temperature sensor, an impedance sensor, or a capacitance sensor.

14. The ophthalmic device of claim 12, wherein the characteristic comprises impedance associated with a movement of a ciliary muscle of the user.

15. The ophthalmic device of claim 12, wherein the characteristic comprises vibration associated with a movement of a ciliary muscle of the user.

16. The ophthalmic device of claim 12, wherein the characteristic comprises capacitance associated with a position or movement of one or more of an upper eyelid and a lower eyelid of the user.

17. The ophthalmic device of claim 12, wherein the characteristic comprises temperature on or adjacent the eye of the user.

18. An ophthalmic device comprising:
an ophthalmic lens configured to be disposed on or in an eye of a user;
a variable optic element incorporated into the ophthalmic lens, the variable optic element being configured to change a refractive power of the ophthalmic lens;
a sensor disposed in the ophthalmic lens, the sensor configured to detect a characteristic of a user of the ophthalmic device, the sensor further configured to provide a sensor output; and
a processor disposed in the ophthalmic lens, the processor configured to determine communication data based on the sensor output;
a power source configured to supply power to at least one of the ophthalmic lens, the sensor, and the processor; and
a light-emitting device configured to transmit a light signal outwardly from the ophthalmic device, the light signal representing the communication data, wherein the light-emitting device comprises:
a photonic transmitter comprising an electro-luminescent (EL) device; and
a driving circuit electrically coupled to the photonic transmitter and configured to cause the photonic transmitter to generate the light signal based on the communication data, wherein the driving circuit is configured to generate a first voltage larger than a second voltage of the power source and switch a connection between the photonic transmitter and the first voltage on and off to generate the light signal.

19. The ophthalmic device of claim 18, wherein the driving circuit comprises an H-bridge comprising two high-voltage p-channel metal-oxide semiconductor (HVPMOS) transistors configured to alternate between supplying the first voltage to a positive terminal of the photonic transmitter and supplying the first voltage to a negative terminal of the photonic transmitter.

20. The ophthalmic device of claim 19, wherein the driving circuit comprises a resistive level shifter configured to control gates of the two HVPMOS transistors.

21. The ophthalmic device of claim 19, wherein the driving circuit comprises a floating level shifter configured to control gates of the two HVPMOS transistors.

22. The ophthalmic device of claim 18, wherein the driving circuit comprises a charge pump configured to multiply the second voltage of the power source to generate the first voltage.

23. The ophthalmic device of claim 22, wherein the driving circuit comprises a storage capacitor electrically coupled to an output of the charge pump and configured to store the first voltage.

24. The ophthalmic device of claim 18, wherein the driving circuit is configured to perform on-off key switching to cause the photonic transmitter to transmit pulse signals based on the communication data.

25. The ophthalmic device of claim 18, further comprising an optical layer disposed outward from the light-emitting device and configured to one or more of collimate and focus the light signal.

26. The ophthalmic device of claim 18, wherein the power source comprises a battery.

27. The ophthalmic device of claim 18, wherein the ophthalmic lens comprises a contact lens.

28. The ophthalmic device of claim 27, wherein the contact lens comprises one or more of a soft contact lens or a hybrid contact lens having a hard component and a soft component.

29. The ophthalmic device of claim 18, wherein the sensor comprises one or more contacts configured to make direct contact with a tear film of the eye.

30. The ophthalmic device of claim 18, wherein the sensor is a displacement sensor, a temperature sensor, an impedance sensor, or a capacitance sensor.

31. The ophthalmic device of claim 18, wherein the characteristic comprises impedance associated with a movement of a ciliary muscle of the user.

32. The ophthalmic device of claim 18, wherein the characteristic comprises vibration associated with a movement of a ciliary muscle of the user.

33. The ophthalmic device of claim 18, wherein the characteristic comprises capacitance associated with a position or movement of one or more of an upper eyelid and a lower eyelid of the user.

34. The ophthalmic device of claim 18, wherein the characteristic comprises temperature on or adjacent the eye of the user.

35. An ophthalmic device comprising:
an ophthalmic lens configured to be disposed on or in an eye of a user;
a variable optic element incorporated into the ophthalmic lens, the variable optic element being configured to change a refractive power of the ophthalmic lens;
a light detection device configured to generate a data signal based on light received at the ophthalmic device, wherein the light detection device comprises:
a photonic detector configured to convert light pulses into an electrical signals;
a filter electrically coupled to the photonic detector and configured to output filtered signals within a predetermined frequency range based on the electrical signals; and
a converter electrically coupled to the filter and configured to output the data signal based on the filtered signals, wherein the data signal comprises a digital signal of variable pulse width based on time-varying characteristics of the filtered signals; and
a processor disposed in the ophthalmic lens, the processor configured to determine communication data based on the data signal.

36. The ophthalmic device of claim 35, wherein the converter comprises a first comparator configured to output a first signal in response to receiving a voltage above a first reference voltage and a second comparator configured to output a second signal in response to receiving a voltage below a second reference voltage.

37. The ophthalmic device of claim 36, wherein the converter comprises a time-to-digital converter configured output the digital signal based on the first signal and the second signal.

38. The ophthalmic device of claim 35, further comprising an optical layer disposed outward from the light detection device and configured to focus light on at least a portion of the light detection device.

39. The ophthalmic device of claim 35, further comprising an optical layer disposed outward from the light detection device and configured to filter out outside of a frequency range associated with a signal transmitter configured to transmit photonic signals to the ophthalmic device.

40. The ophthalmic device of claim 35, wherein the photonic detector comprises a reverse-biased diode.

41. The ophthalmic device of claim 35, wherein the photonic detector comprises a silicon avalanche photo diode.

42. The ophthalmic device of claim 35, wherein the light detection device is fabricated using a complimentary metal-oxide semiconductor (CMOS) process, and wherein the light detection device is disposed on a silicon based integrated circuit.

43. The ophthalmic device of claim 35, wherein the filter is configured to filter out ambient light changes.

44. The ophthalmic device of claim 35, wherein the filter comprises a trans-impedance amplifier configured to amplify the filtered signals within the predetermined frequency range.

45. The ophthalmic device of claim 35, wherein the ophthalmic lens comprises a contact lens.

46. The ophthalmic device of claim 45, wherein the contact lens comprises one or more of a soft contact lens or a hybrid contact lens having a hard component and a soft component.

47. The ophthalmic device of claim 35, wherein the processor is configured to detect an eye blink by comparing a pulse width of a digital signal to a template.

48. The ophthalmic device of claim 35, further comprising a sensor disposed in the ophthalmic lens, wherein the processor is configured to modify a parameter associated with the sensor based on the communication data.

49. The ophthalmic device of claim 48, wherein the sensor comprises one or more contacts configured to make direct contact with a tear film of the eye.

50. The ophthalmic device of claim 48, wherein the sensor is a displacement sensor, a temperature sensor, an impedance sensor, or a capacitance sensor.

51. An ophthalmic device comprising:
an ophthalmic lens configured to be disposed on or in an eye of a user;
a variable optic element incorporated into the ophthalmic lens, the variable optic element being configured to change a refractive power of the ophthalmic lens;
a sensor disposed in the ophthalmic lens, the sensor configured to detect a characteristic of a user of the ophthalmic device, the sensor further configured to provide a sensor output;
a processor disposed in the ophthalmic lens, the processor configured to determine communication data based on the sensor output;
a power source configured to supply power to at least one of the ophthalmic lens, the sensor, and the processor; and
a light-emitting device configured to transmit a light signal outwardly from the ophthalmic device, the light signal representing the communication data, wherein the light-emitting device comprises:
a photonic transmitter comprising a light-emitting transistor; and
a driving circuit electrically coupled to the photonic transmitter and configured to cause the photonic transmitter to generate the light signal based on the communication data, wherein the driving circuit is configured to generate a first voltage larger than a second voltage of the power source and cause a current based on the first voltage to switch on and off for the photonic transmitter to generate the light signal.

52. The ophthalmic device of claim 51, wherein the light-emitting transistor comprises a silicon light-emitting transistor.

53. The ophthalmic device of claim 51, wherein the light-emitting transistor is configured to emit light based on an avalanche effect of charge carriers.

54. The ophthalmic device of claim 53, wherein the driving circuit is configured to apply a reverse bias to one or more terminals of the light-emitting transmitter thereby causing the avalanche effect of charge carriers.

55. The ophthalmic device of claim 51, wherein the light-emitting transistor comprises a first n-doped region, a second n-doped region, and a p-doped region, wherein the driving circuit is configured to supply the first voltage to a first n-doped region, and a time-varying signal to one or more of the p-doped region and the second n-doped region.

56. The ophthalmic device of claim 55, wherein the time-varying signal comprises a signal that switches between a third voltage and a fourth voltage, wherein the third voltage is zero.

57. The ophthalmic device of claim 51, wherein the driving circuit comprises a charge pump configured to multiply the second voltage of the power source to generate the first voltage.

58. The ophthalmic device of claim 57, wherein the driving circuit comprises a storage capacitor electrically coupled to an output of the charge pump and configured to store the first voltage.

59. The ophthalmic device of claim 51, wherein the driving circuit is configured to perform on-off key switching to cause the photonic transmitter to transmit pulse signals based on the communication data.

60. The ophthalmic device of claim 51, further comprising an optical layer disposed outward from the light-emitting device and configured to one or more of collimate and focus the light signal.

61. The ophthalmic device of claim 51, wherein the power source comprises a battery.

62. The ophthalmic device of claim 51, wherein the ophthalmic lens comprises a contact lens.

63. The ophthalmic device of claim 62, wherein the contact lens comprises one or more of a soft contact lens or a hybrid contact lens having a hard component and a soft component.

64. The ophthalmic device of claim 51, wherein the sensor comprises one or more contacts configured to make direct contact with a tear film of the eye.

65. The ophthalmic device of claim 51, wherein the sensor is a displacement sensor, a temperature sensor, an impedance sensor, or a capacitance sensor.

66. The ophthalmic device of claim 51, wherein the characteristic comprises impedance associated with a movement of a ciliary muscle of the user.

67. The ophthalmic device of claim 51, wherein the characteristic comprises vibration associated with a movement of a ciliary muscle of the user.

68. The ophthalmic device of claim 51, wherein the characteristic comprises capacitance associated with a position or movement of one or more of an upper eyelid and a lower eyelid of the user.

69. The ophthalmic device of claim 51, wherein the characteristic comprises temperature on or adjacent the eye of the user.

70. An ophthalmic device comprising:
an ophthalmic lens configured to be disposed on or in an eye of a user;
a variable optic element incorporated into the ophthalmic lens, the variable optic element being configured to change a refractive power of the ophthalmic lens;
a processor disposed in the ophthalmic lens, the processor configured to determine communication data associated with communicating with the user;
a power source configured to supply power to at least one of the ophthalmic lens and the processor; and
a light-emitting device configured to transmit a light signal from the ophthalmic device to the eye of the user, the light signal representing the communication data, wherein the light-emitting device comprises:
a photonic transmitter; and
a driving circuit electrically coupled to the photonic transmitter and configured to cause the photonic transmitter to generate the light signal based on the communication data, wherein the driving circuit is configured to generate a first voltage larger than a second voltage of the power source and switch a connection between the photonic transmitter and the first voltage on and off to generate the light signal.

71. The ophthalmic device of claim 70, wherein the photonic transmitter comprises one or more of a reverse-biased silicon diode (RSiD), an organic LED (OLED), a silicon light-emitting transistor, or an electro-luminescent (EL) device.

72. The ophthalmic device of claim 70, wherein the light-emitting device is configured to transmit the light signal to the eye via an optical guide.

73. The ophthalmic device of claim 70, wherein the light-emitting device is positioned to transmit the light signal to pupil of the eye.

74. The ophthalmic device of claim 70, wherein the processor is configured to determine communication data associated with communicating with the user based on communication data received from an external source.

75. The ophthalmic device of claim 74, wherein the external source comprises one or more of a smart device, a watch, a mobile phone, or a wireless transmitter.

76. The ophthalmic device of claim 74, wherein communication data received from the external source comprises one or more of an alert, a notification, or a message.

77. The ophthalmic device of claim 70, wherein the driving circuit comprises a charge pump configured to multiply the second voltage of the power source to generate the first voltage.

78. The ophthalmic device of claim 77, wherein the driving circuit comprises a storage capacitor electrically coupled to an output of the charge pump and configured to store the first voltage.

79. The ophthalmic device of claim 70, wherein the driving circuit is configured to perform on-off key switching to cause the photonic transmitter to transmit pulse signals based on the communication data.

80. The ophthalmic device of claim 70, wherein the power source comprises a battery.

81. The ophthalmic device of claim 70, wherein the ophthalmic lens comprises a contact lens.

82. The ophthalmic device of claim 81, wherein the contact lens comprises one or more of a soft contact lens or a hybrid contact lens having a hard component and a soft component.

83. The ophthalmic device of claim 70, wherein the processor is configured to determine communication data associated with communicating with the user based on sensor data of a sensor of the ophthalmic device.

84. The ophthalmic device of claim 83, wherein the sensor comprises one or more contacts configured to make direct contact with a tear film of the eye.

85. The ophthalmic device of claim 83, wherein the sensor is a displacement sensor, a temperature sensor, an impedance sensor, or a capacitance sensor.

86. The ophthalmic device of claim 83, wherein the processor is configured to determine a characteristic of the user based on the sensor data and determine communication data based on the characteristic.

87. The ophthalmic device of claim 86, wherein the characteristic comprises impedance associated with a movement of a ciliary muscle of the user.

88. The ophthalmic device of claim 86, wherein the characteristic comprises vibration associated with a movement of a ciliary muscle of the user.

89. The ophthalmic device of claim 86, wherein the characteristic comprises capacitance associated with a position or movement of one or more of an upper eyelid and a lower eyelid of the user.

90. The ophthalmic device of claim 86, wherein the characteristic comprises temperature on or adjacent the eye of the user.
